(19) United States
(12) Patent Application Publication
(10) Pub. No.: US 2024/0179888 A1
(43) Pub. Date: May 30, 2024

(54) SEMICONDUCTOR MEMORY DEVICES

(71) Applicant: Samsung Electronics Co., Ltd., Suwon-si (KR)

(72) Inventors: Jaecheon YONG, Suwon-si (KR); Daehong KO, Goyang-si (KR)

(73) Assignees: Samsung Electronics Co., Ltd., Suwon-si (KR); INDUSTRY-ACADEMIC COOPERATION FOUNDATION, YONSEI UNIVERSITY, Seoul (KR)

(21) Appl. No.: 18/492,093

(22) Filed: Oct. 23, 2023

(30) Foreign Application Priority Data
Nov. 25, 2022 (KR) 10-2022-0160679

(51) Int. Cl. H10B 12/00

(52) U.S. Cl. CPC H10B 12/30; H10B 12/03; H10B 12/05

(57) ABSTRACT

A semiconductor memory device includes a source layer, a semiconductor layer including a semiconductor protrusion structure, and a drain layer arranged in a first horizontal direction on a substrate, a cell capacitor extending in the first horizontal direction on the substrate and including a lower electrode layer, a capacitor dielectric film, and an upper electrode layer connected to the drain layer, a bit line extending in a vertical direction on the substrate and connected to the source layer, and a gate structure covering the semiconductor protrusion structure and including a gate dielectric film on the semiconductor protrusion structure and a gate electrode film on the gate dielectric film. A value of a first thickness of an end portion of the semiconductor protrusion structure facing the drain layer is greater than a value of a second thickness of another end portion of the semiconductor protrusion structure facing the source layer.

### CROSS-REFERENCE TO RELATED APPLICATION

This application is based on and claims priority under 35 U.S.C. § 119 to Korean Patent Application No. 10-2022-0160679, filed on Nov. 25, 2022, in the Korean Intellectual Property Office, the disclosure of which is incorporated by reference herein in its entirety.

### BACKGROUND

Various example embodiments relate to a semiconductor memory device, and more particularly, to a three-dimensional semiconductor memory device.

According to requirements or expectation for miniaturization, multi-functionality, and high performance of electronic products, high-capacity semiconductor memory devices are being required or desired, and increased integration is being required or pursued to provide high-capacity semiconductor memory devices. As the integration of two-dimensional semiconductor memory devices is mainly determined based on an area occupied by a unit memory cell, the integration of such two-dimensional semiconductor memory devices is increasing but still limited. Therefore, three-dimensional semiconductor memory devices for increasing a memory capacity by stacking a plurality of memory cells in a vertical direction on a substrate have been proposed.

### SUMMARY

Various example embodiments provide a three-dimensional semiconductor memory device with improved integrity.

To do so, example embodiments provide a semiconductor memory device.

According to various example embodiments, there is provided a semiconductor memory device on a substrate, arranged in a first horizontal structure, and including a source layer, a semiconductor layer including a semiconductor protrusion structure, and a drain layer, a cell capacitor extending in the first horizontal direction on the substrate and including an upper electrode layer, a capacitor dielectric film, and a lower electrode layer connected to the drain layer, a bit line extending in a vertical direction on the substrate and connected to the source layer, and a gate structure covering the semiconductor protrusion structure and including a gate dielectric film on the semiconductor protrusion structure and a gate electrode film on the gate dielectric film A value of a first thickness of an end portion of the semiconductor protrusion structure facing the drain layer is greater than a value of a second thickness of another end portion of the semiconductor protrusion structure facing the source layer, and the source layer has the second thickness at the other end portion of the semiconductor protrusion structure and has a third thickness, which is greater than the second thickness, as a maximum thickness.

Alternatively or additionally according to some example embodiments, there is provided a semiconductor memory device including a plurality of horizontal semiconductor structures on a substrate and arranged in a first horizontal direction, each of the plurality of horizontal structures including a source layer, a semiconductor layer including a semiconductor protrusion structure, and a drain layer. The plurality of horizontal semiconductor structures are apart from one another in columns in a second horizontal direction, which is orthogonal to the first horizontal direction, and in rows in a vertical direction/The semiconductor memory device further includes a plurality of cell capacitors extending in the first horizontal direction from the plurality of horizontal semiconductor structures and each including a lower electrode layer connected to the drain layer of each of the plurality of horizontal semiconductor structures, a capacitor dielectric film covering each of the plurality of lower electrode layers, and an upper electrode layer covering the capacitor dielectric film. The semiconductor memory device further includes a plurality of gate structures covering the semiconductor protrusion structures of the plurality of semiconductor layers and extending in the second horizontal direction, the plurality of gate structures each including a gate dielectric film on the semiconductor protrusion structure and a gate electrode film on the gate dielectric film. Each of the plurality of semiconductor protrusion structures extends from an end of the semiconductor protrusion structure facing each of the plurality of drain layers to another end of the semiconductor protrusion structure facing each of the source layers, with a decrease from a first thickness to a second thickness that is less than the first thickness, and each of the source layers has a polygon shape having facets extending from the other end of each of the semiconductor protrusion structures, with increase from the second thickness to a third thickness that is greater than the second thickness in the first horizontal direction.

Alternatively or additionally according to some example embodiments, there is provided a semiconductor memory device including a plurality of horizontal semiconductor structures on a substrate and arranged in a first horizontal direction, each of the plurality of horizontal semiconductor structures including a source layer, a semiconductor layer including a semiconductor protrusion structure, and a drain layer, the plurality of horizontal semiconductor structures being arranged apart in columns in a second horizontal direction, orthogonal to the first horizontal direction, and in rows in a vertical direction. The semiconductor memory device additionally includes a plurality of cell capacitors extending in the first horizontal direction from the plurality of horizontal semiconductor structures, the plurality of cell capacitors each including a lower electrode layer connected to the source layer of each of the plurality of horizontal semiconductor structures, a capacitor dielectric film covering each of the plurality of lower electrode layers, and an upper electrode layer covering the capacitor dielectric film. The semiconductor memory device additionally includes a plurality of bit lines extending in the vertical direction on the substrate, connected to the source layers of horizontal semiconductor structures arranged apart from one another in the vertical direction from among the plurality of horizontal semiconductor structures, and apart from one another in the second horizontal direction, a plurality of gate structures surrounding the semiconductor protrusion structures apart from one another in the second horizontal direction from among the plurality of semiconductor protrusion structures and extending in the second horizontal direction, the plurality of gate structure each including a gate dielectric film on the semiconductor protrusion structure and a gate electrode film on the gate dielectric film, and a plurality of word line contacts extending in the vertical direction and apart from one another in the second horizontal direction. The plurality of word line contacts are apart from the plurality of bit lines in the first horizontal direction and are connected to the gate electrode film of each of the plurality of gate structures. Each of the plurality of semiconductor protrusion structures extends with a decrease from a first thickness to a second thickness that is less than the first thickness, from an end of the semiconductor protrusion structure facing each of the plurality of drain layers to another end of the semiconductor protrusion structure facing each of the source layers, and each of the source layers extends in the first horizontal direction from the other end of each of the semiconductor protrusion structures, with an increase in a thickness from the second thickness to a third thickness that is greater than the second thickness, and a thickness of each of the drain layers extends in a constant thickness between an end of each of the semiconductor protrusion structures and each of the plurality of cell capacitors.

### BRIEF DESCRIPTION OF THE DRAWINGS

Various example embodiments of the inventive concept will be more clearly understood from the following detailed description taken in conjunction with the accompanying drawings in which:

FIGS. 1A to 18B are diagrams shown according to a process order to describe a method of manufacturing a semiconductor memory device according to some example embodiments;

FIGS. 19A to 19D are diagrams of a semiconductor memory device according to some example embodiments;

FIGS. 20A and 20B are diagrams of a semiconductor memory device according to some example embodiments;

FIGS. 21A to 22B are diagrams shown according to a process order to describe a method of manufacturing a semiconductor memory device according to some example embodiments;

FIGS. 23A to 23C are diagrams of a semiconductor memory device according to some example embodiments;

FIGS. 24A to 25B are diagrams shown according to a process order to describe a method of manufacturing a semiconductor memory device according to some example embodiments;

FIGS. 26A to 26C are diagrams of a semiconductor memory device according to some example embodiments; and

FIG. 27 is an equivalent circuit diagram of a cell array of a semiconductor memory device according to some example embodiments.

### DETAILED DESCRIPTION OF VARIOUS EXAMPLE EMBODIMENTS

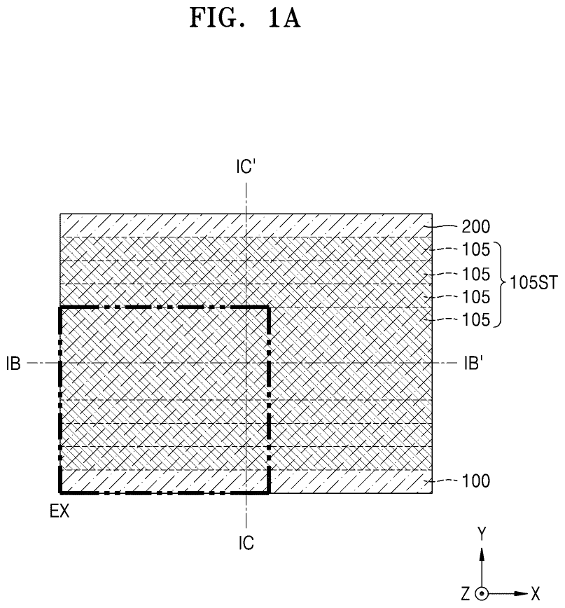

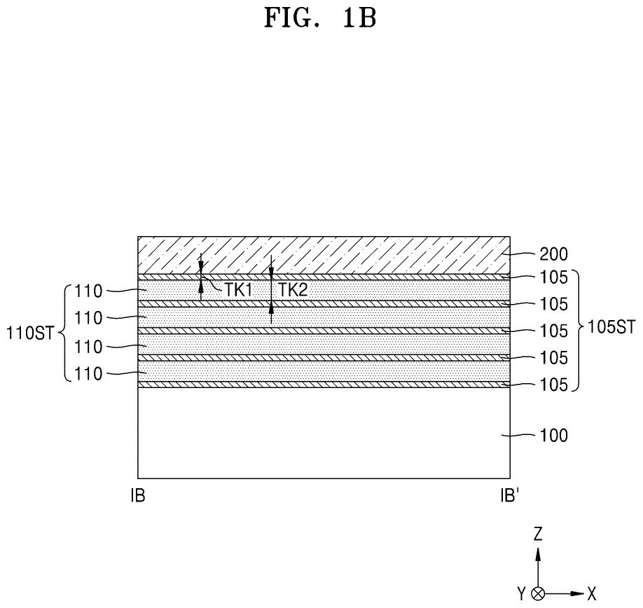

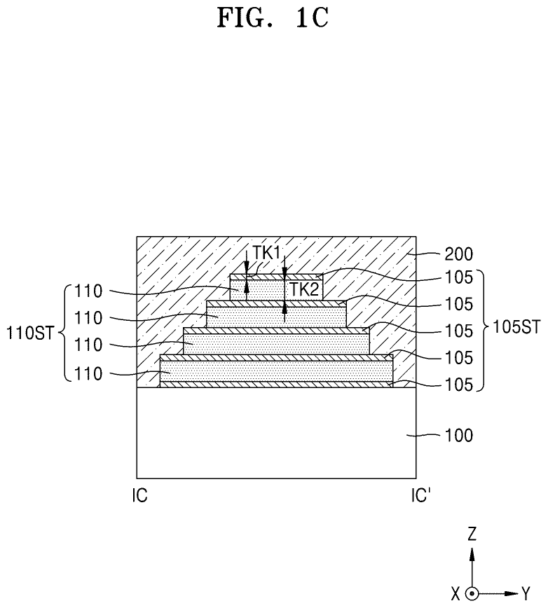

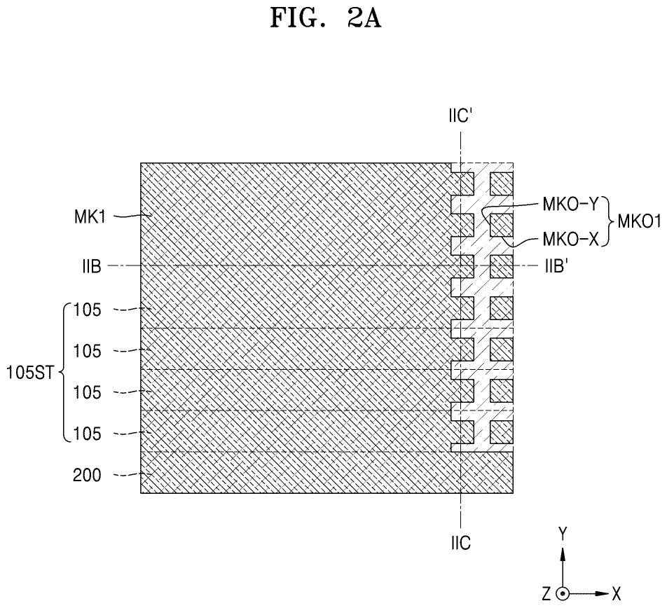

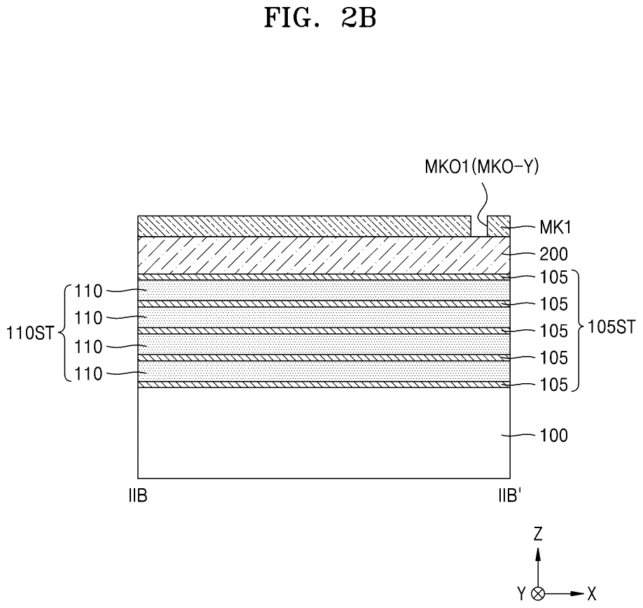

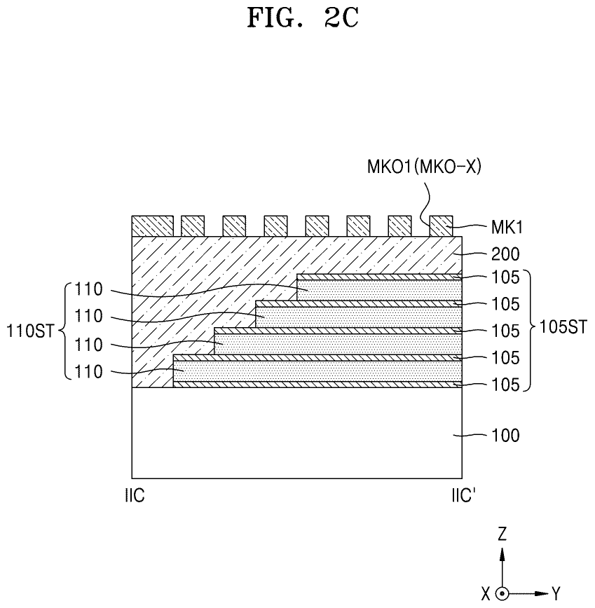

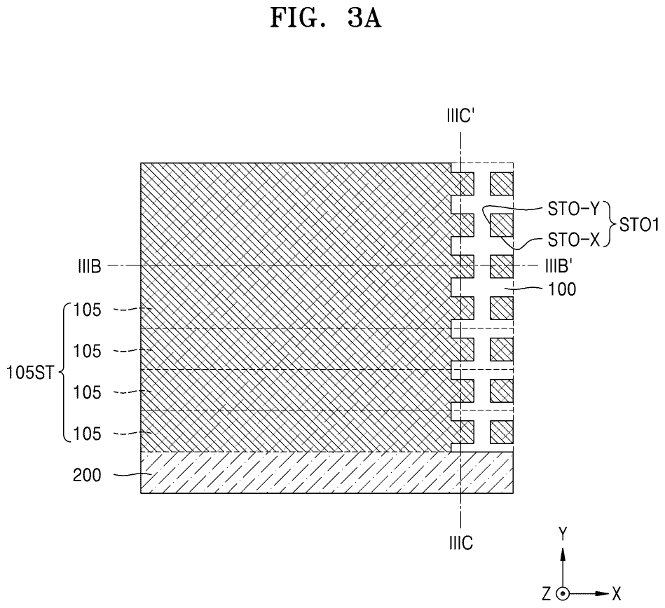

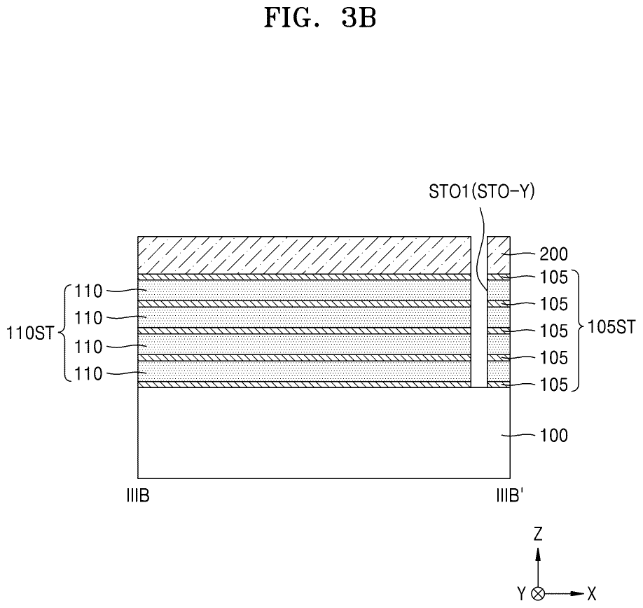

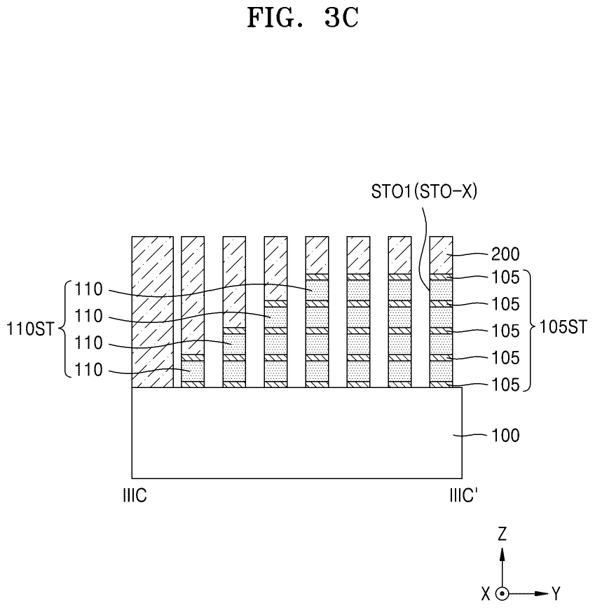

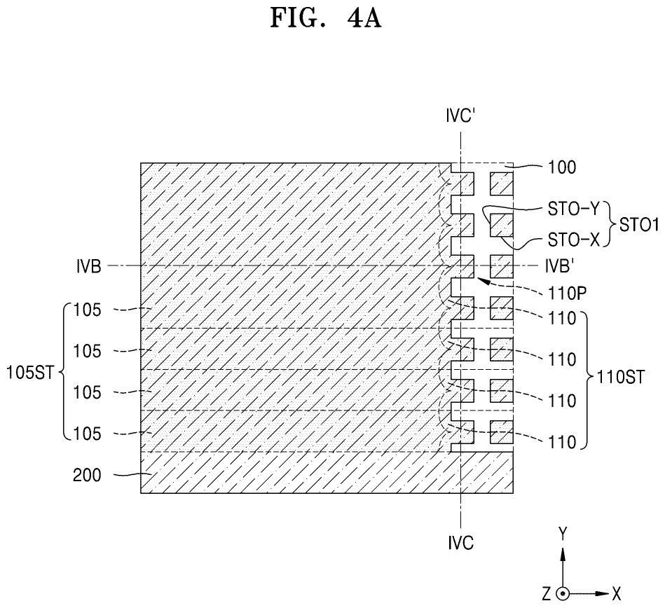

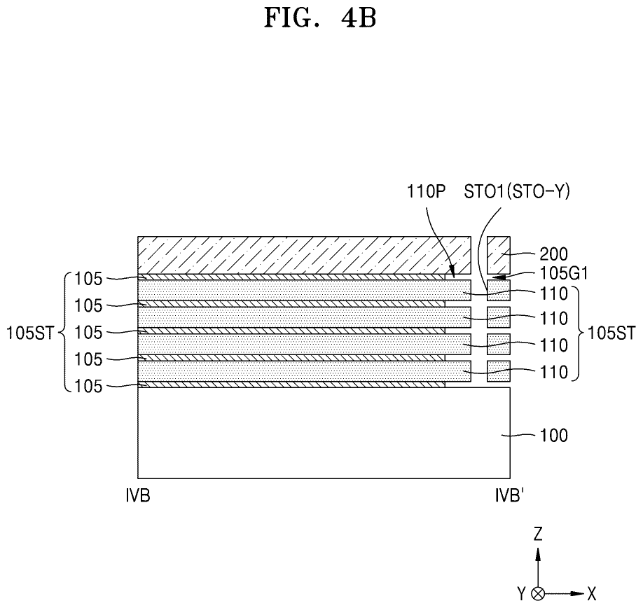

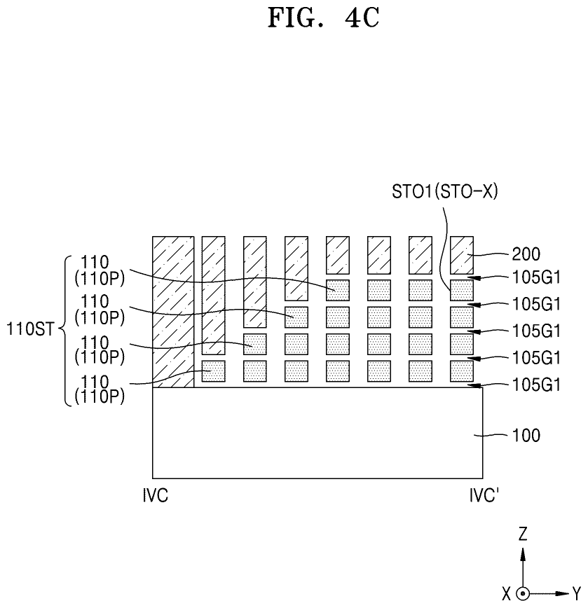

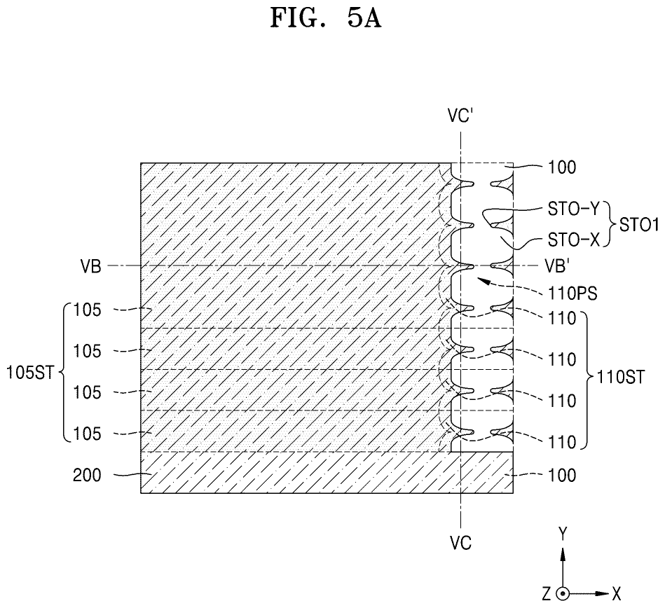

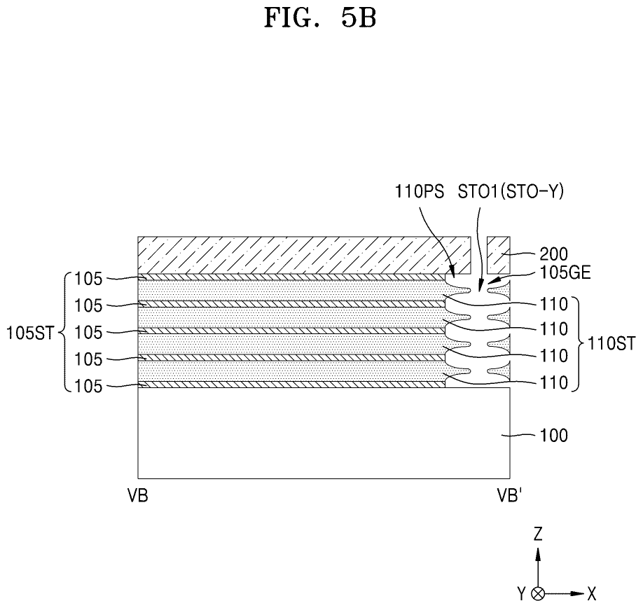

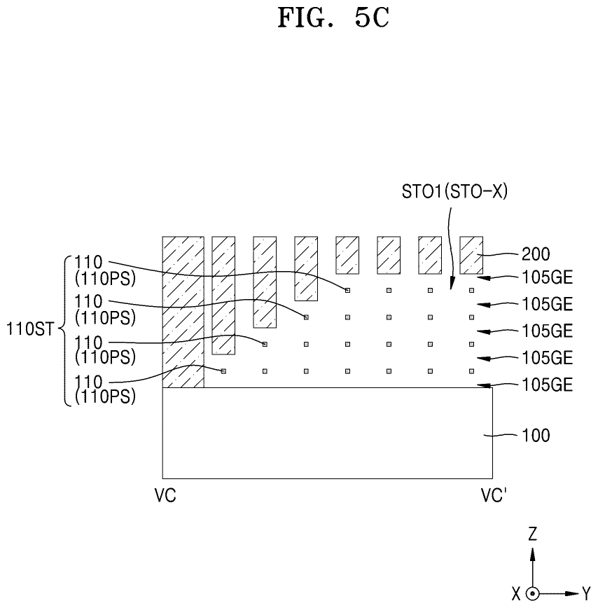

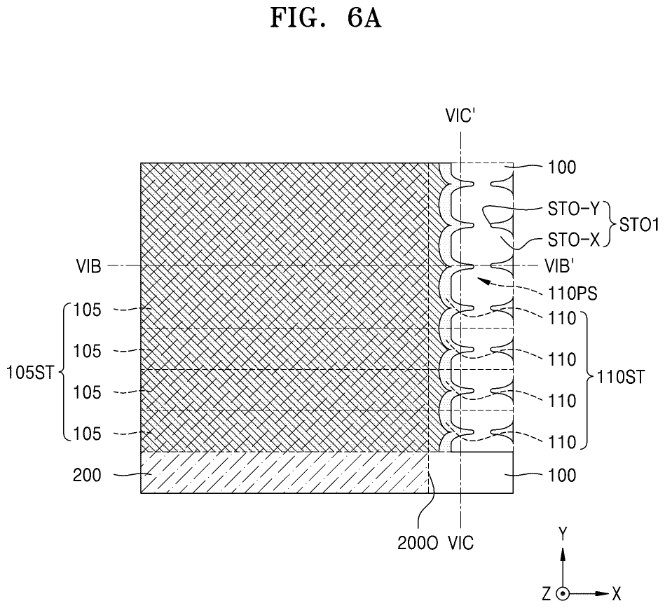

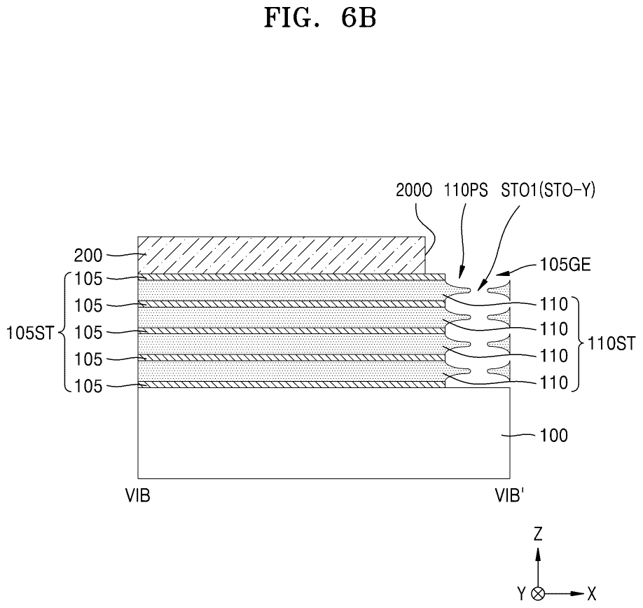

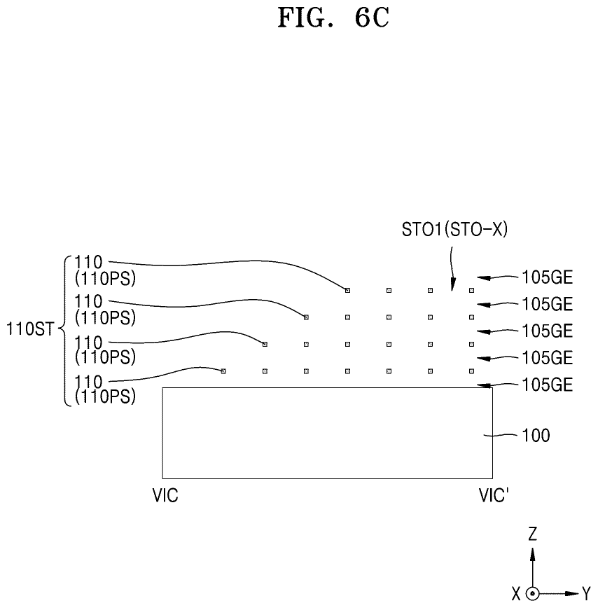

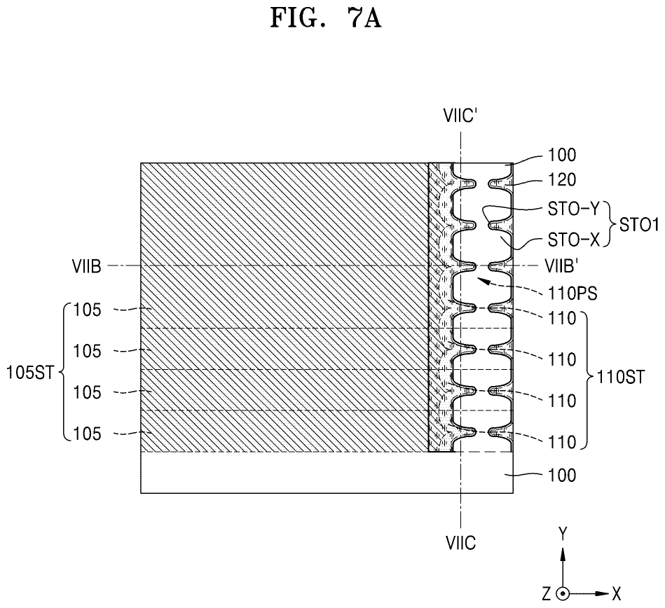

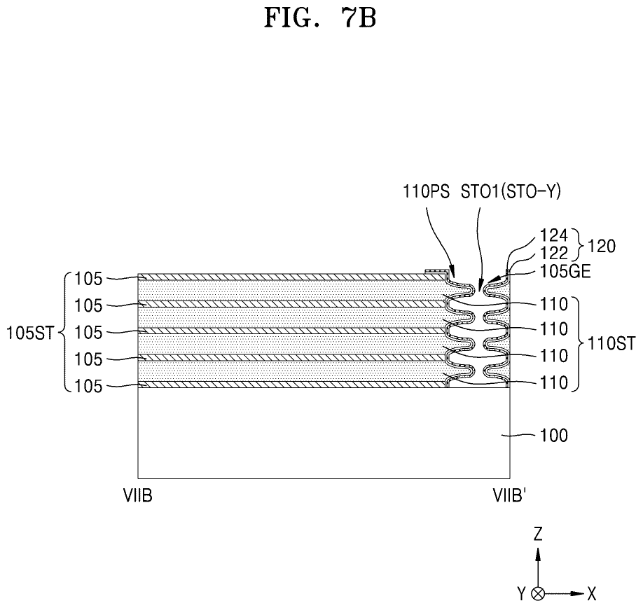

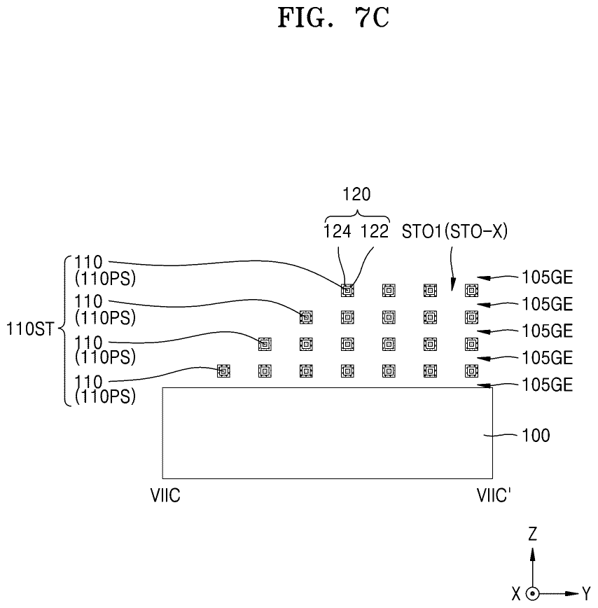

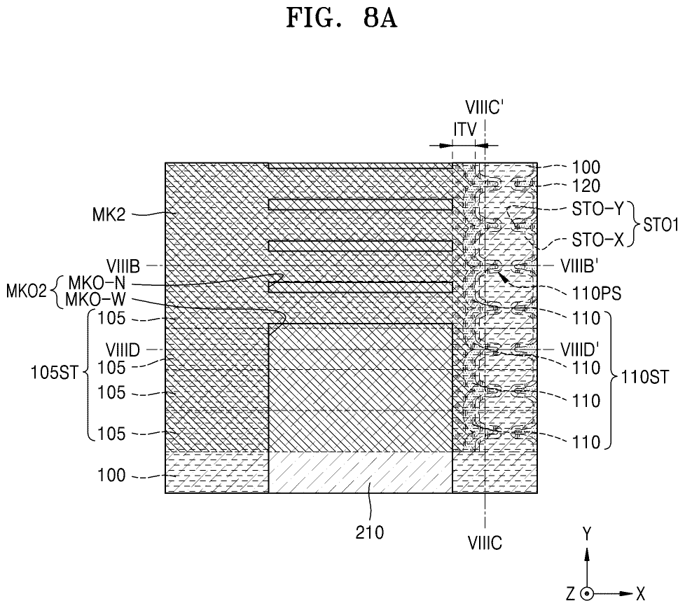

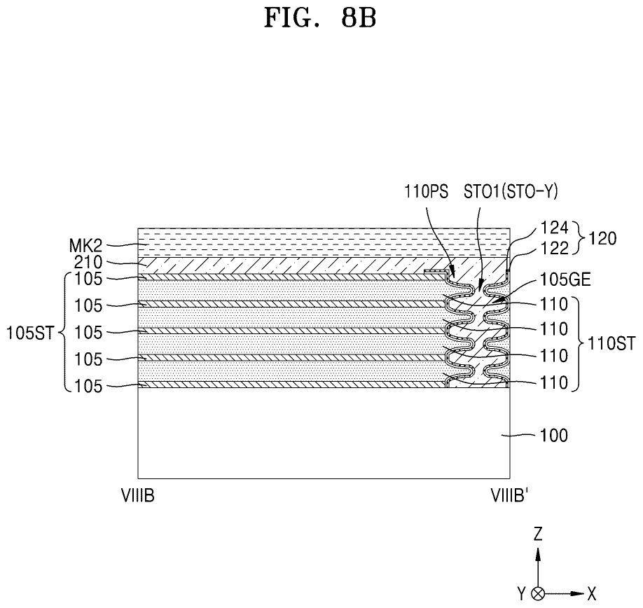

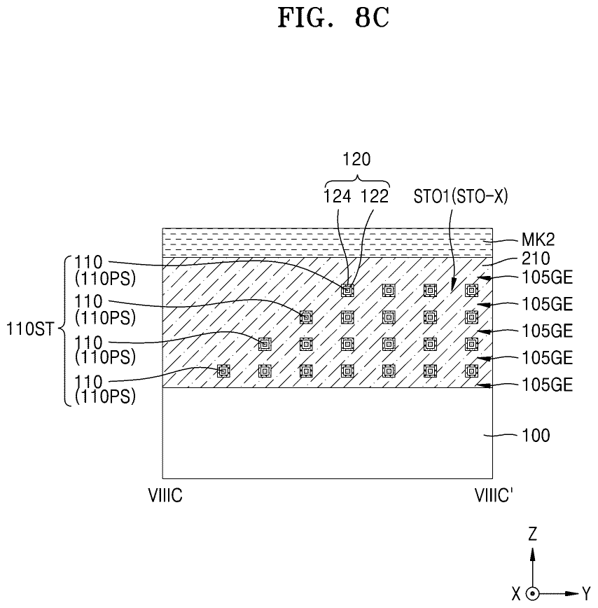

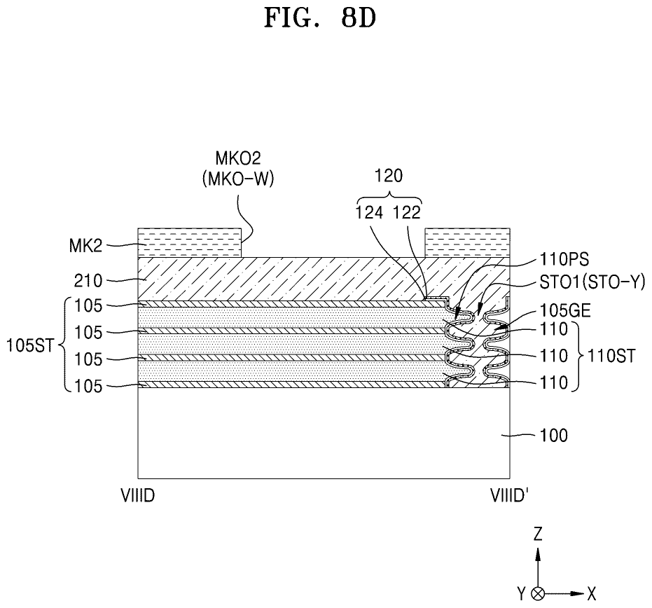

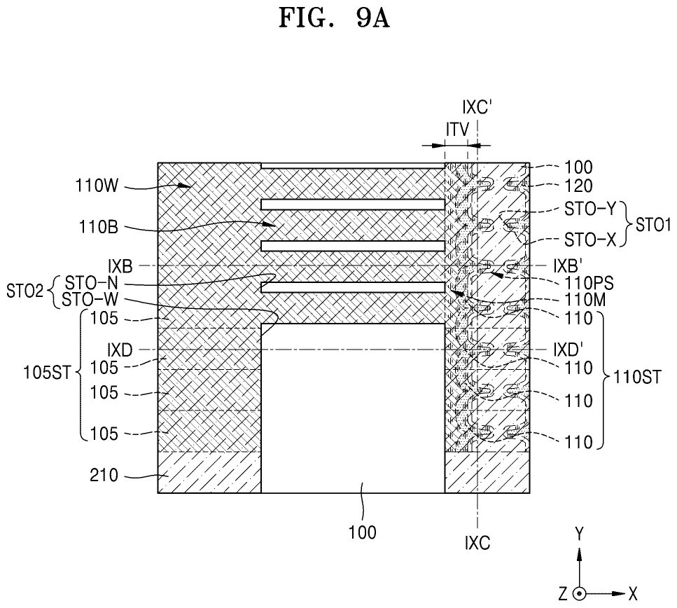

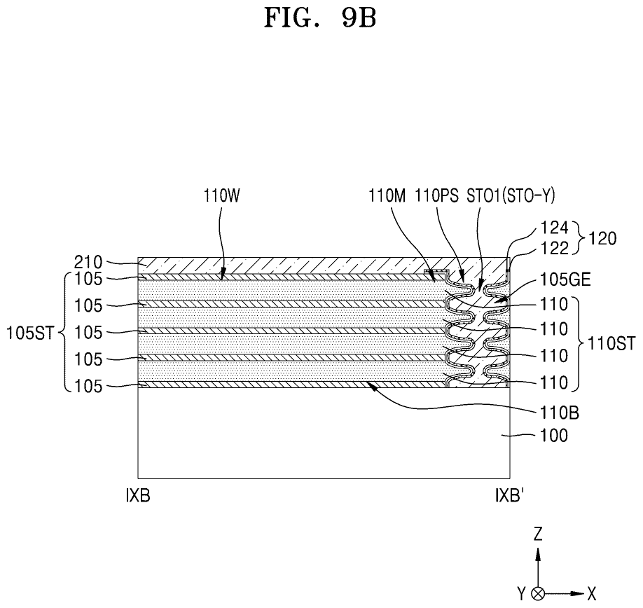

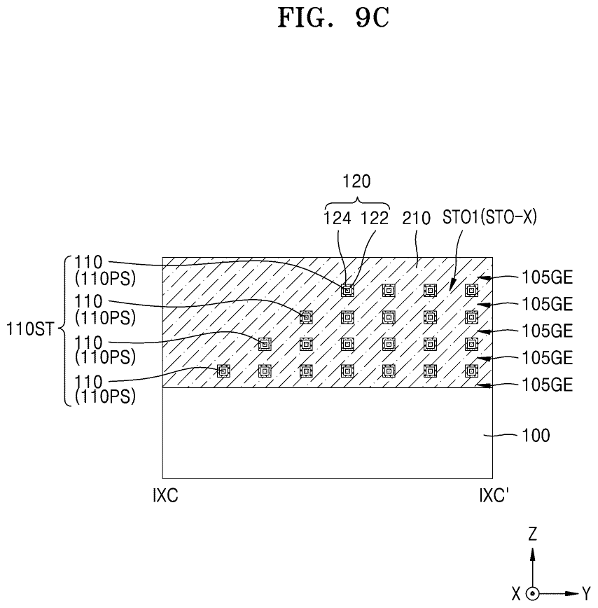

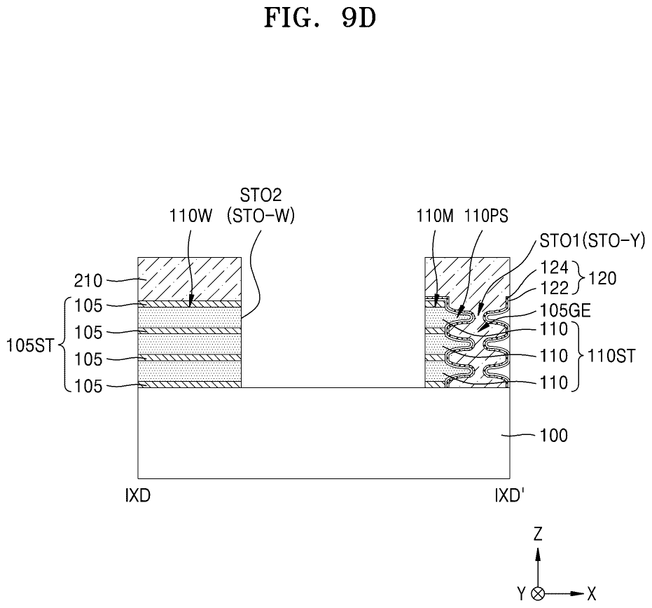

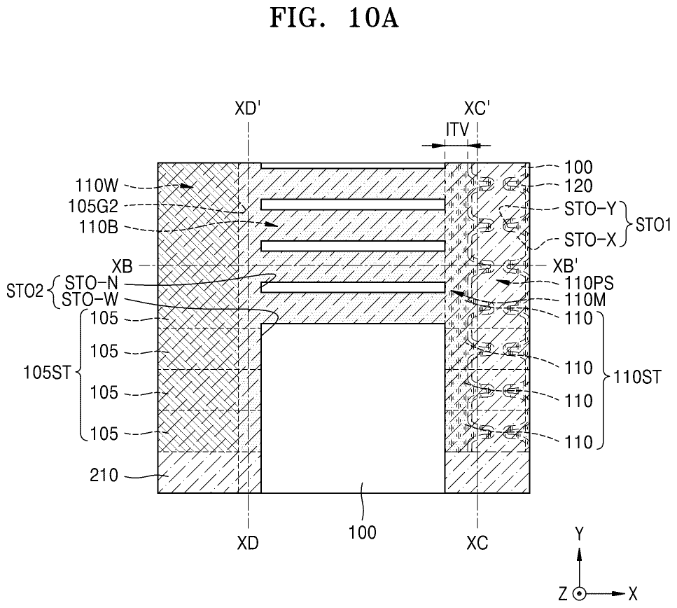

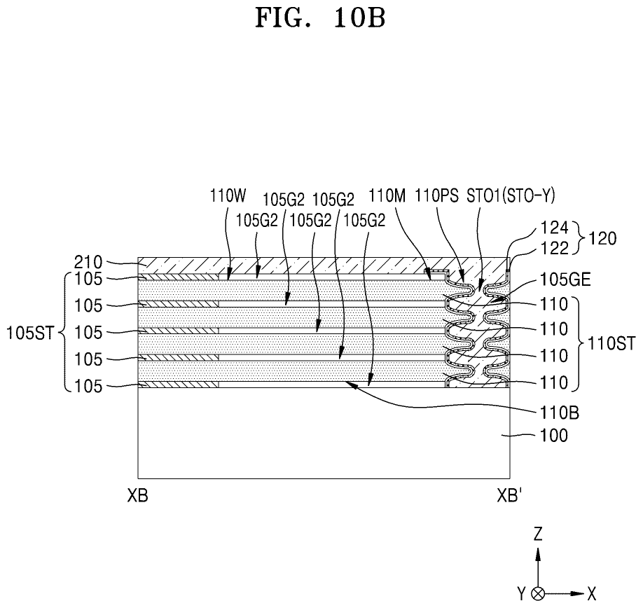

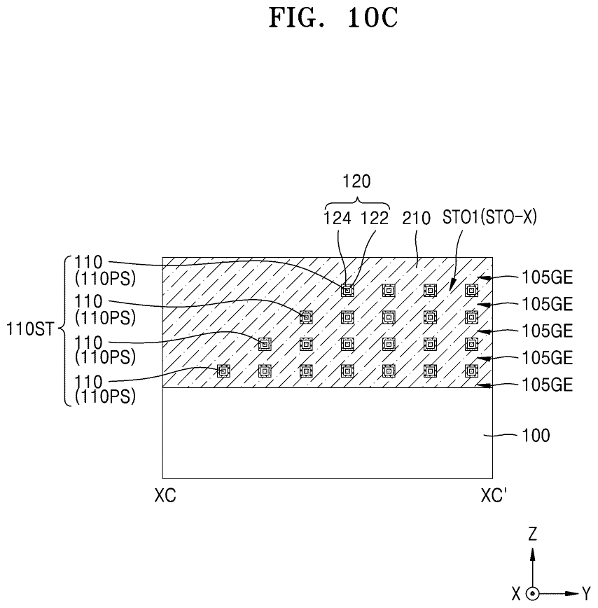

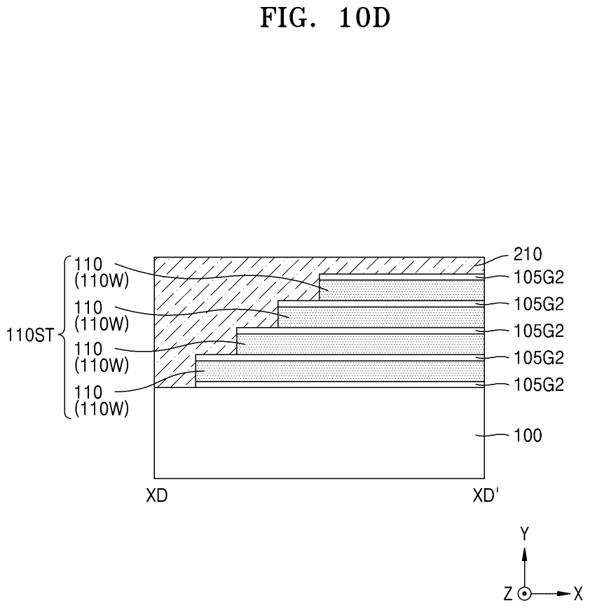

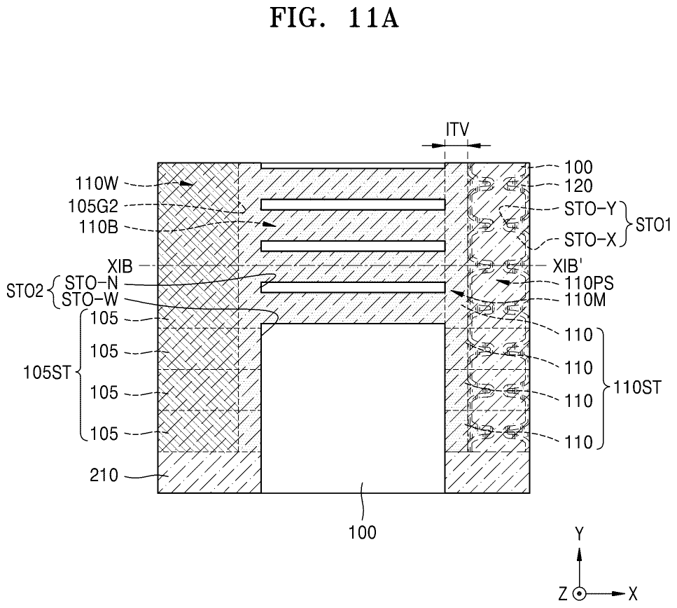

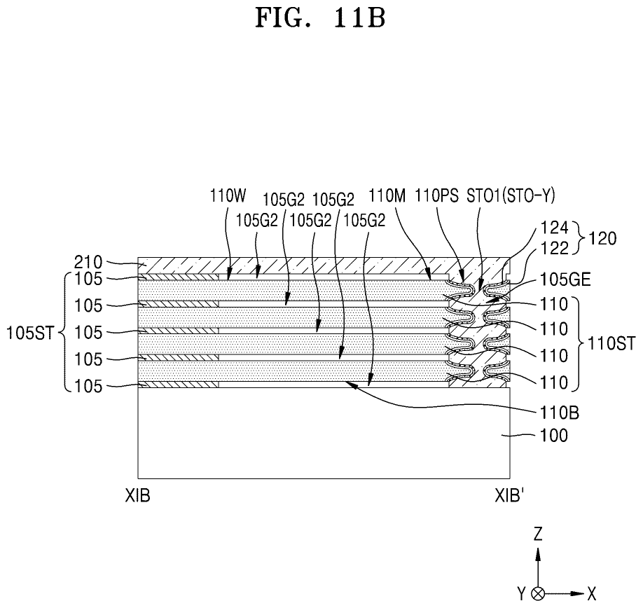

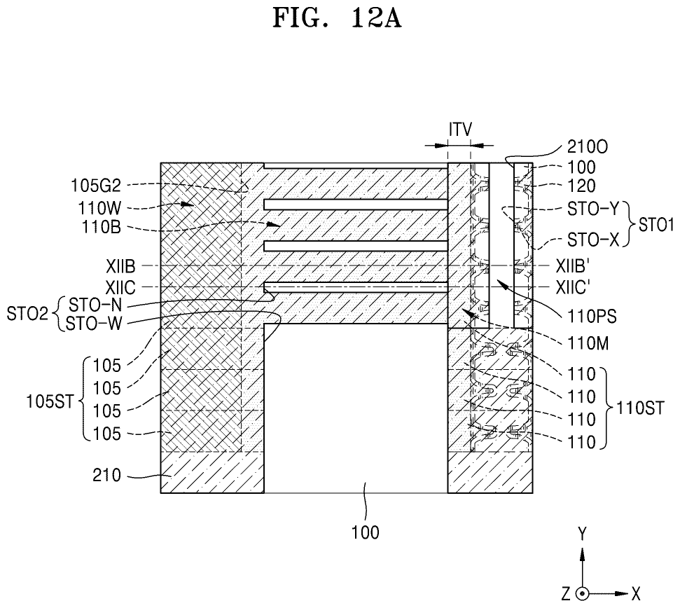

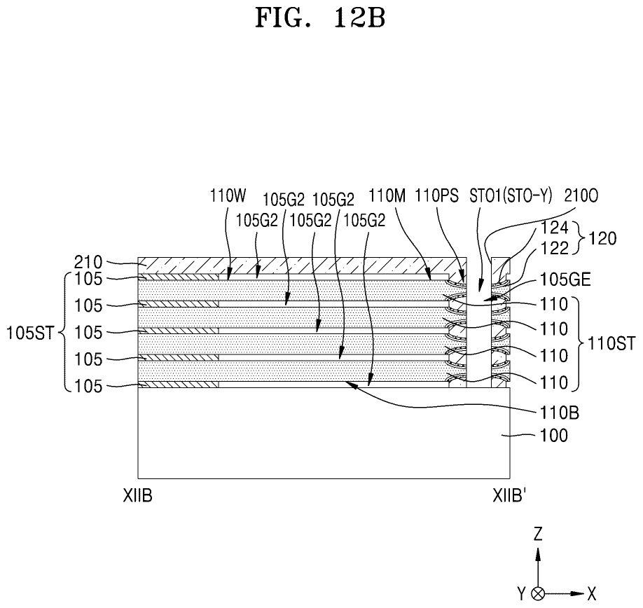

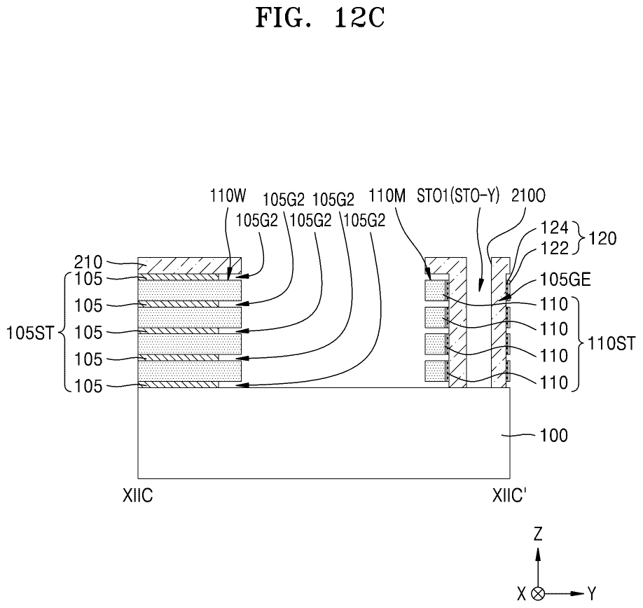

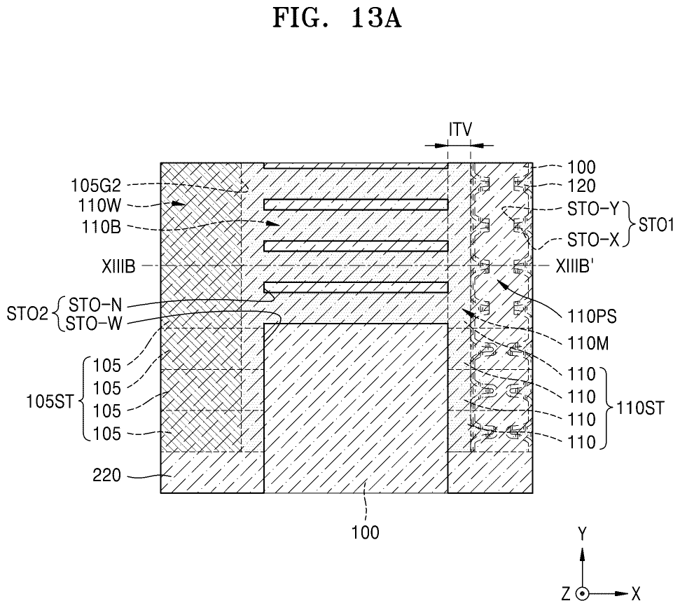

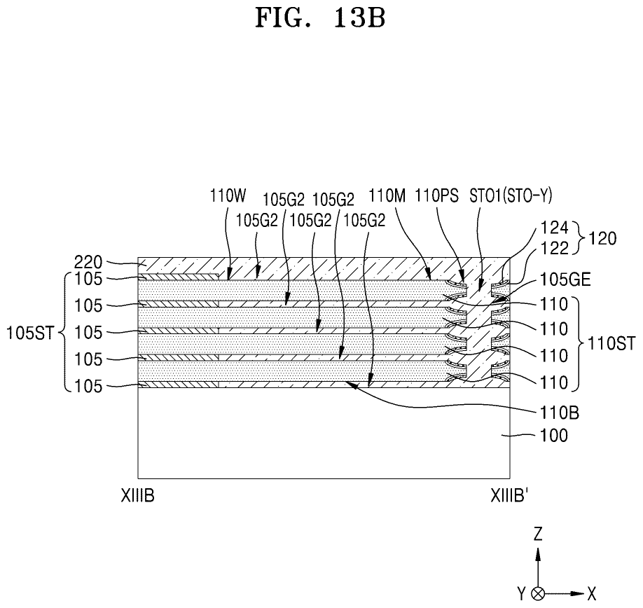

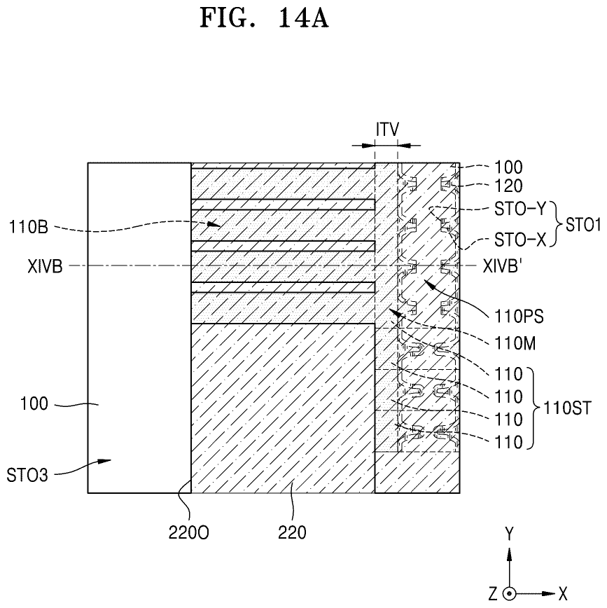

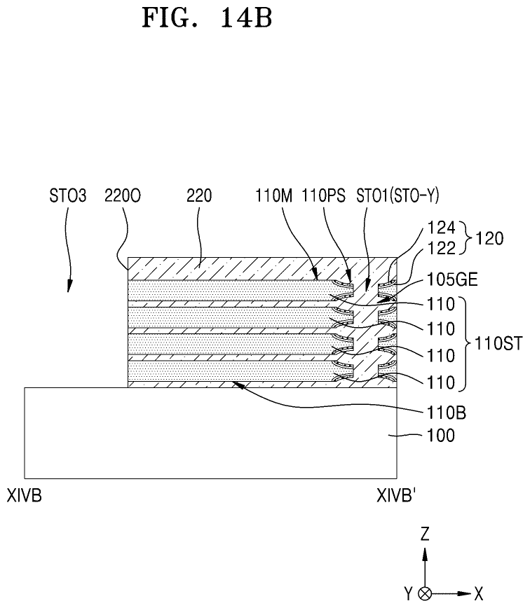

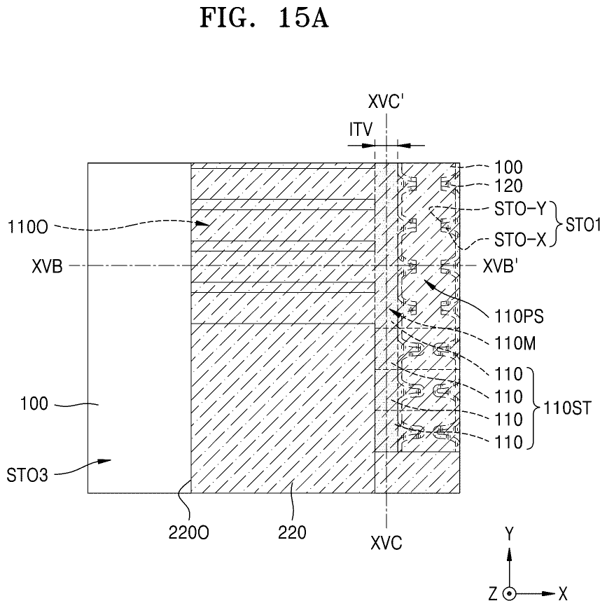

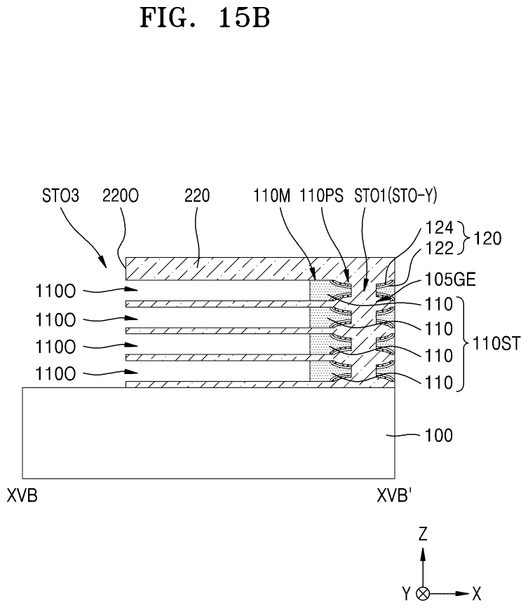

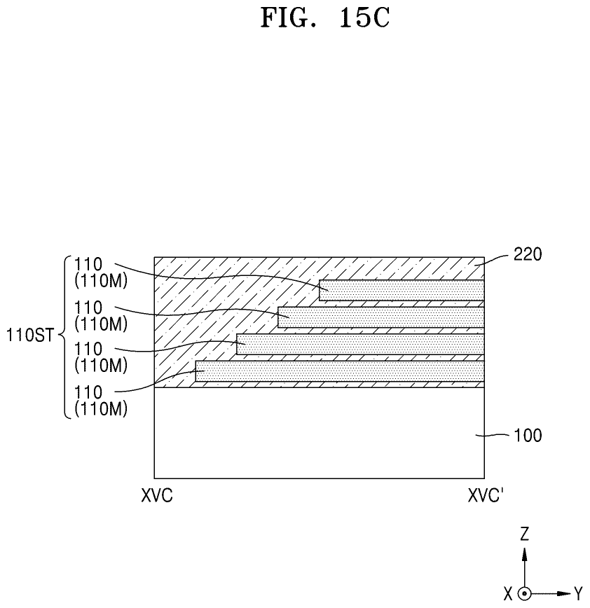

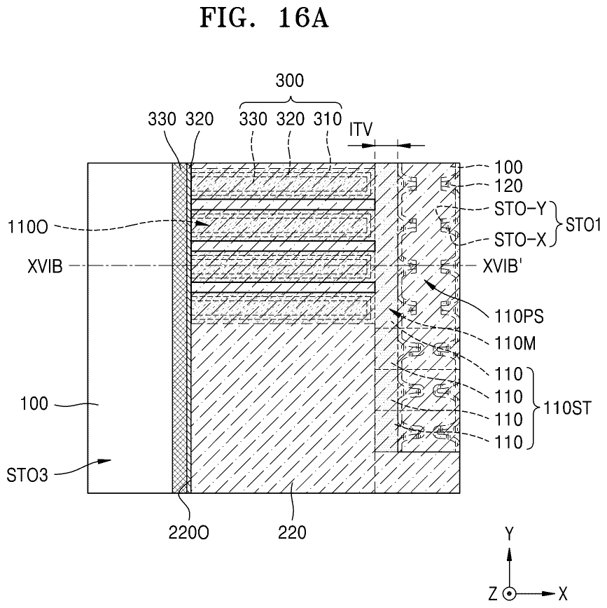

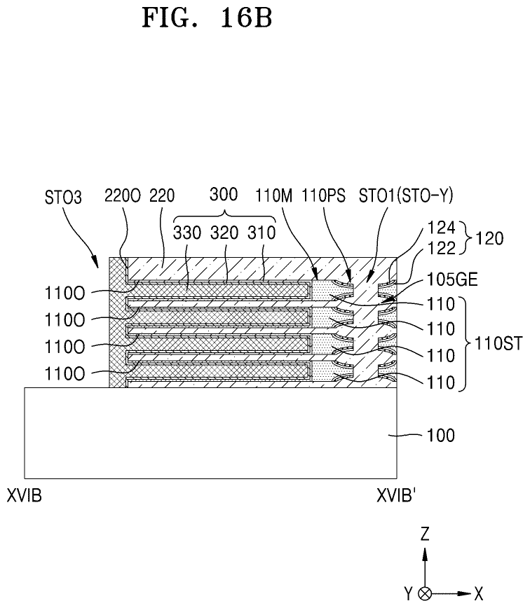

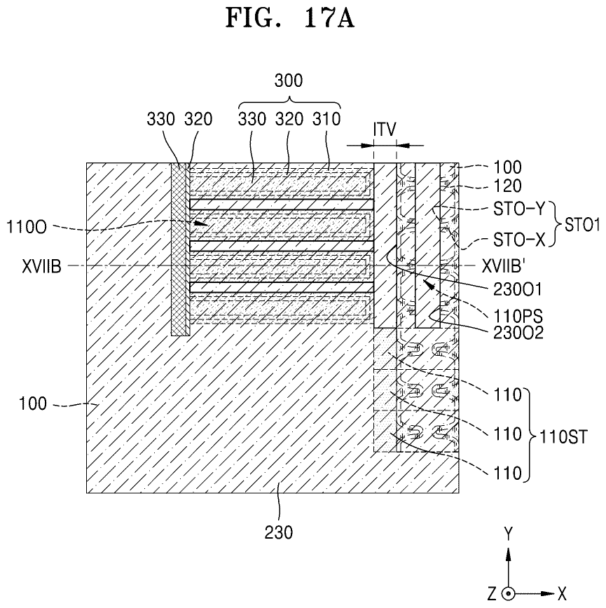

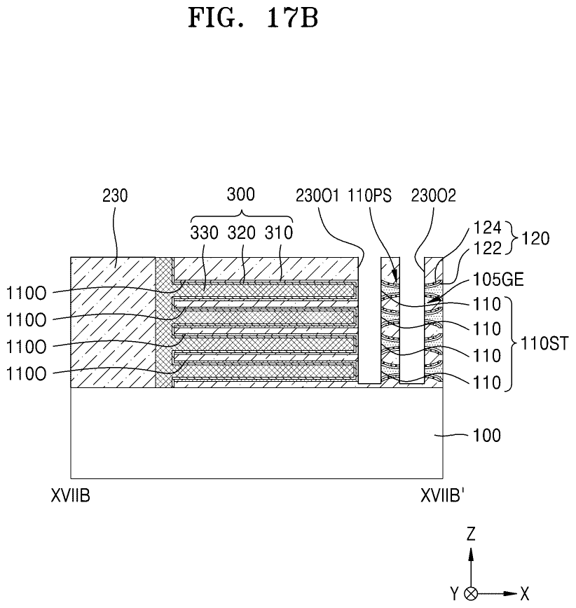

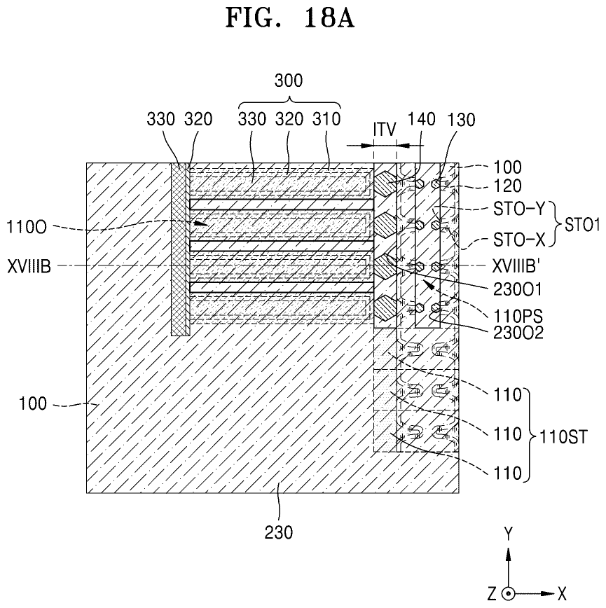

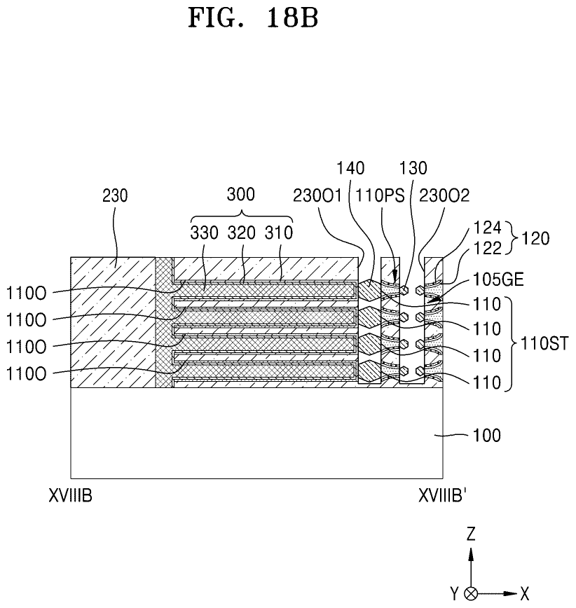

FIGS. 1A to 18B are diagrams shown according to a process order to describe a method of manufacturing a semiconductor memory device 1 according to various example embodiments. More particularly, FIGS. 1A, 2A, 3A, 4A, 5A, 6A, 7A, 8A, 9A, 10A, 11A, 12A, 13A, 14A, 15A, 16A, 17A, and 18A are each a top-plan view seen from top; FIGS. 1B, 2B, 3B, 4B, 5B, 6B, 7B, 8B, 9B, 10B, 11B, 12B, 13B, 14B, 15B, 16B, 17B, and 18B are each a diagram of a cross-section taken along line IB-IB′ shown in FIG. 1A, line IIB-IIB′ shown in FIG. 2A, line IIIB-IIIB′ shown in FIG. 3A, line IVB-IVB′ shown in FIG. 4A, line VB-VB′ shown in FIG. 5A, line VIB-VIB′ shown in FIG. 6A, line VIIB-VIIB′ shown in FIG. 7A, line VIIIB-VIIIB′ shown in FIG. 8A, line IXB-IXB′ shown in FIG. 9A, line XB-XB′ shown in FIG. 10A, line XIB-XIB′ shown in FIG. 11A, line XIIB-XIIB′ shown in FIG. 12A, line XIIIB-XIIIB′ shown in FIG. 13A, line XIVB-XIVB′ shown in FIG. 14A, line XVB-XVB′ shown in FIG. 15A, line XVIB-XVIB′ shown in FIG. 16A, line XVIIB-XVIIB′ shown in FIG. 17A, and line XVIIIB-XVIIIB′ shown in FIG. 18A; FIGS. 1C, 2C, 3C, 4C, 5C, 6C, 7C, 8C, 9C, 10C, 12C, and 15C are each a diagram of a cross-section taken along line IC-IC′ shown in FIG. 1A, line IIC-IIC′ shown in FIG. 2A, line IIIC-IIIC′ shown in FIG. 3A, line IVC-IVC′ shown in FIG. 4A, line VC-VC′ shown in FIG. 5A, line VIC-VIC′ shown in FIG. 6a, line VIIC-VIIC′ shown in FIG. 7A, line VIIIC-VIIIC′ shown in FIG. 8A, line IXC-IXC′ shown in FIG. 9A, line XC-XC′ shown in FIG. 10A, line XIIC-XIIC′ shown in FIG. 12A, and line XVC-XVC′ shown in FIG. 15A, and FIGS. 8D, 9D, and 10D are each a diagram of a cross-section taken along line VIIID-VIIID′ shown in FIG. 8A, line IXD-IXD′ shown in FIG. 9A, and line XD-XD′ shown in FIG. 10A. In addition, FIGS. 2A to 17B are top-plan views and cross-sectional views corresponding to portion EX shown in FIG. 1A.

Referring to FIGS. 1A to 1C, a plurality of sacrificial layers 105 and a plurality of semiconductor layers 110 may be formed on a substrate 100. The plurality of sacrificial layers 105 and the plurality of semiconductor layers 110 may be alternately stacked on the substrate 100, and may be formed to have the same, or different, thicknesses as each other. The plurality of sacrificial layers 105 may collectively be referred to as a stacked sacrificial structure 105ST, and the plurality of semiconductor layers 110 may collectively be referred to as a stacked semiconductor structure 110ST. The stacked sacrificial structure 105ST may include the plurality of sacrificial layers 105 arranged apart from one another in a vertical direction (a Z direction) on the substrate 100. The stacked semiconductor structure 110ST may include the plurality of semiconductor layers 110 arranged apart from one another in the vertical direction (the Z direction) on the substrate 100.

The stacked semiconductor structure 110ST may be in the stacked sacrificial structure 105ST in an interposed manner. For example, each of the plurality of semiconductor layers 110 may be between two sacrificial layers 105 adjacent to each other and apart from each other in the vertical direction (the Z direction). The number of sacrificial layers 105 included in the stacked sacrificial structure 105ST may be greater by one than the number of semiconductor layers 110 included in the stacked semiconductor structure 110ST. Although FIGS. 1A to 1C illustrate that the stacked sacrificial structure 105ST includes five sacrificial layers 105 and the stacked semiconductor structure 110ST includes four semiconductor layers 110, this is only an example, example embodiments are not limited thereto. For example, the stacked sacrificial structure 105ST may include six or more, or tens to thousands of sacrificial layers 105, and the stacked semiconductor structure 110ST may include five or more, or tens to hundreds of semiconductor layers 110.

The substrate 100 may be or may include, for example, silicon (Si), e.g., crystalline Si, polycrystalline Si, or amorphous Si. Alternatively or additionally, the substrate 100 may include a semiconductor element, such as germanium (Ge), or at least one compound semiconductor selected from among silicon germanium (SiGe), silicon carbide (SiC), gallium arsenide (GaAs), indium arsenide (InAs), and indium phosphide (InP). Alternatively, the substrate 100 may include a silicon-on-insulator (SOI) substrate or a germanium-on-insulator (GeOI) substrate. For example, the substrate 100 may include a buried oxide (BOX) layer. The substrate 100 may include a conductive area, for example, a well doped with impurities and/or a structure doped with impurities.

The plurality of sacrificial layers 105 and the plurality of semiconductor layers 110 may each include a semiconductor material. The sacrificial layer 105 may include a semiconductor material having an etching selectivity (e.g. a greater etch rate) with respect to the semiconductor layer 110. In some example embodiments, the sacrificial layer 105 may have an etching selectivity with respect to the substrate 100. In some example embodiments, a semiconductor layer 110 may include a material having the same or similar etching properties such as those of the substrate 100, or may include a same material as the substrate 100. For example, each of the plurality of sacrificial layers 105 may include SiGe (and may not include Si), and each of the plurality of semiconductor layers 110 may include Si (and may not include SiGe).

In some example embodiments, the plurality of sacrificial layers 105 and the plurality of semiconductor layers 110 may each include a monocrystalline (single crystal) semiconductor material. For example, the plurality of sacrificial layers 105 may each include monocrystalline SiGe, and the plurality of semiconductor layers 110 may each include monocrystalline Si.

In some example embodiments, the plurality of semiconductor layers 110 may each include a two-dimensional (2D) semiconductor material or an oxide semiconductor material. For example, the 2D semiconductor material may include MoS₂, WSe₂, Graphene, Carbon Nano Tube, or combinations thereof. For example, the oxide semiconductor material may include InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, InₓGa_{y}O or combinations thereof. For example, each of the plurality of semiconductor layers 110 may include a single layer or layers including the oxide semiconductor material. In some example embodiments, each of the plurality of semiconductor layers 110 may include a material having a bandgap energy that is greater than a bandgap energy of Si. For example, each of the plurality of semiconductor layers 110 may include a material having a bandgap energy from about 1.5 eV to about 5.6 eV. For example, each of the plurality of semiconductor layers 110 may include a material that may have optimal channel properties when having a bandgap energy from about 2.0 eV to about 4.0 eV.

The plurality of sacrificial layers 105 and the plurality of semiconductor layers 110 may be formed through one or more of a chemical vapor deposition (CVD) process, a plasma enhanced CVD (PECVD) process, or an atomic layer deposition (ALD) process. In some example embodiments, each of the plurality of sacrificial layers 105 and the plurality of semiconductor layers 110 may be formed in a monocrystalline state using a layer thereunder, e.g., the substrate 100, the sacrificial layer 105, or the semiconductor layer 110, as a seed layer, or may be formed in a monocrystalline state through a thermal treatment process.

The plurality of sacrificial layers 105 may be formed in an approximately same thickness. The plurality of semiconductor layers 110 may be formed in an approximately same thickness. Each of the plurality of sacrificial layers 105 may have a first film thickness TK1, and each of the plurality of semiconductor layers 110 may have a second film thickness TK2. The first film thickness TK1 may have a value that is less than a value of the second film thickness TK2. For example, the second film thickness TK2 may be twice or four times the first film thickness TK1. In some example embodiments, the first film thickness TK1 may be from about 10 nm to about 20 nm, and the second film thickness TK2 may be from about 20 nm to about 50 nm.

The plurality of sacrificial layers 105 and the plurality of semiconductor layers 110 may be respectively formed to be approximately horizontal width in a first horizontal direction (an X direction). The plurality of semiconductor layers 110 may be formed away from the substrate 100 in the vertical direction (the Z direction), in a small horizontal width in a second horizontal direction (the Y direction) that is orthogonal to the first horizontal direction (the X direction). For example, a semiconductor layer 110 at the bottom of the plurality of semiconductor layers 110 may be formed in a greatest horizontal width in the second horizontal direction (the Y direction), a semiconductor layer 110 at the top of the plurality of semiconductor layers 110 may be formed in a smallest horizontal width in the second horizontal direction (the Y direction), and the plurality of semiconductor layers 110 may be away from the substrate 100 in the vertical direction (the Z direction) with a horizontal thickness decreasing at an approximately same ratio in the second horizontal direction (the Y direction). The plurality of semiconductor layers 110 may have a step shape at two ends in the second horizontal direction (the Y direction). For example, the plurality of semiconductor layers 110 may be formed such that a gap between horizontal widths in the second horizontal direction (the Y direction) of pairs of semiconductor layers 110 adjacent to one another in the vertical direction (the Z direction) is approximately the same.

A horizontal width in the second horizontal direction (the Y direction) of the sacrificial layer 105 covering a top surface of any one semiconductor layer 110 from among the plurality of semiconductor layers 110 may be approximately identical to a horizontal width in the second horizontal direction (the Y direction) of any one of the semiconductor layer 110 from among the plurality of semiconductor layers 110. A horizontal width in the second horizontal direction (the Y direction) of the sacrificial layer 105 covering a bottom surface of the semiconductor layer 110 at the bottom of the plurality of semiconductor layers 110 may be approximately identical to a horizontal width in the second horizontal direction (the Y direction) of the semiconductor layer 110 at the bottom of the plurality of semiconductor layers 110. That is, among the plurality of sacrificial layers 105, the sacrificial layer 105 at the bottom and the sacrificial layer 105 thereon may have an approximately same horizontal width in the second horizontal direction (the Y direction). Among the plurality of sacrificial layers 105, other sacrificial layers 105 except the sacrificial layer 105 at the bottom of the plurality of sacrificial layers 105 may be formed away in the vertical direction (the Z direction) from the substrate 100, with a small horizontal width in the second horizontal direction (the Y direction). Among the plurality of sacrificial layers 105, the other sacrificial layers 105 except the sacrificial layer 105 at the bottom of the plurality of sacrificial layers 105 may have a step shape at two ends in the second horizontal direction (the Y direction)

A first insulating layer 200 covering the stacked sacrificial structure 105ST and the stacked semiconductor structure 110ST may be formed on the substrate 100. For example, the first insulating layer 200 may include an oxide; however, example embodiments are not limited thereto. The first insulating layer 200 may be formed on the substrate 100 by forming a first preliminary insulating material layer fully or at least partially covering the stacked sacrificial structure 105ST and the stacked semiconductor structure 110ST, and then performing a planarization process of removing a portion of top of the first preliminary insulating material layer. For example, the first insulating layer 200 may be formed by performing a CMP process and/or an etch-back process in which a portion of the top of the first preliminary insulating material layer is removed.

A vertical level of a top surface of the first insulating layer 200 may be higher than a vertical level of a top surface of the stacked sacrificial structure 105ST, e.g., a vertical level of a top surface of the sacrificial layer 105 at the top of the plurality of sacrificial layers 105. For example, the first insulating layer 200 may be formed to cover both of the top surface of the stacked sacrificial structure 105ST and the top surface of the stacked semiconductor structure 110ST.

Referring to FIGS. 2A to 2C, a first mask layer MK1 having a first mask opening MKO1 is formed on the first insulating layer 200. The first mask layer MK1 may include a photoresist and/or a hardmask material. The first mask opening MKO1 may expose a portion of the first insulating layer 200.

The first mask opening MKO1 may include a plurality of first horizontal mask openings MKO-X communicating one another and a second horizontal mask opening MKO-Y. The second horizontal mask opening MKO-Y may have a planar shape of a line or bar extending in the second horizontal direction (the Y direction). Each of the plurality of first horizontal mask openings MKO-X may have a planar shape of a line or bar crossing the second horizontal mask opening MKO-Y and extending in the first horizontal direction (the X direction). The plurality of first horizontal mask openings MKO-X may be apart from one another in the second horizontal direction (the Y direction) and may cross the second horizontal mask opening MKO-Y. A pitch in cross-section of the first mask openings MKO1 may be constant; however, example embodiments are not limited thereto.

The number of first horizontal mask openings MKO-X may be greater than the number of semiconductor layers 110. Some of the plurality of first horizontal mask openings MKO-X may each extend in the first horizontal direction (the X direction) along step-shaped risers of the stacked sacrificial structure 105ST and the stacked semiconductor structure 110ST. For example, some of the plurality of first horizontal mask openings MKO-X may overlap in a vertical direction with portions of two treads located at different vertical levels of the step-shaped risers of the stacked sacrificial structure 105ST and stacked semiconductor structure 110ST. Other first horizontal mask openings MKO-X may overlap both of the top surface of the semiconductor layer 110 at the top of the plurality of semiconductor layers 110 and the top surface of the sacrificial layer 105 at the top of the plurality of sacrificial layers 105.

In some example embodiments, the second horizontal mask opening MKO-Y may extend in the second horizontal direction (the Y direction) along centers of the plurality of first horizontal mask openings MKO-X in the first horizontal direction (the X direction).

The second horizontal mask opening MKO-Y may extend in the second horizontal direction (the Y direction) between the stacked sacrificial structure 105ST and the stacked semiconductor structure 110ST. Although FIGS. 2A to 2C illustrate that the first mask layer MK1 has a second horizontal mask opening MKO-Y, this is only an example, and example embodiments are not limited thereto. For example, the first mask layer MK1 may have a plurality of second horizontal mask openings MKO-Y apart from one another in the first horizontal direction (the X direction) and extending in the second horizontal direction (the Y direction), and may also include a plurality of first horizontal mask openings MKO-X respectively crossing the plurality of second horizontal mask openings MKO-Y, apart from one another in the second horizontal direction (the Y direction), and extending in the first horizontal direction (the X direction).

A horizontal width of the first horizontal mask opening MKO-X in the first horizontal direction (the X direction) may have a value greater than a value of a horizontal width of the second horizontal mask opening MKO-Y in the first horizontal direction (the X direction). For example, the horizontal width of the first horizontal mask opening MKO-X in the first horizontal direction (the X direction) may be about 750 nm, and the horizontal width of the second horizontal mask opening MKO-Y in the first horizontal direction (the X direction) may be about 200 nm.

A horizontal width of the first horizontal mask opening MKO-X in the second horizontal direction (the Y direction) may have a value that is less than a value of the horizontal width of the first horizontal mask opening MKO-X in the first horizontal direction (the X direction). For example, the horizontal width of the first horizontal mask opening MKO-X in the second horizontal direction (the Y direction) may be about 250 nm. In some example embodiments, the horizontal widths of the first horizontal mask opening MKO-X in the second horizontal direction (the Y direction) may have a value greater than a value of the horizontal width of the second horizontal mask opening MKO-Y in the first horizontal direction (the X direction).

In some example embodiments, an interval between the plurality of first horizontal mask openings MKO-X in the second horizontal direction (the Y direction) may have a value that is approximately equal to a value of the horizontal width of the first horizontal mask opening MKO-X in the second horizontal direction (the Y direction). For example, the interval between the plurality of first horizontal mask openings MKO-X in the second horizontal direction (the Y direction) may be about 250 nm.

Although FIGS. 2A to 2C illustrate that, among the plurality of first horizontal mask openings MKO-X, a horizontal width in the second horizontal direction (the Y direction) of the first horizontal mask opening MKO-X overlapping a portion of the semiconductor layer 110 at the bottom of the stacked semiconductor structure 110ST in the vertical direction is less than a horizontal width in the second horizontal direction (the Y direction) of another first horizontal mask opening MKO-X, this is only an example, and example embodiments are not limited thereto. For example, the plurality of first horizontal mask openings MKO-X may have an approximately same width in the second horizontal direction (the Y direction).

Referring to FIGS. 2A to 3C, the first insulating layer 200, the stacked sacrificial structure 105ST, and the stacked semiconductor structure 110ST are partially removed using the first mask layer MK1 as an etching mask to form a first opening STO1 penetrating the first insulating layer 200, the stacked sacrificial structure 105ST, and the stacked semiconductor structure 110ST. After forming the first opening STO1, the first mask layer MK1 may be removed. The substrate 100 may be exposed at a bottom surface of the first opening STO1.

The first opening STO1 may include a plurality of first horizontal openings STO-X communicating one another and a second horizontal opening STO-Y. The second horizontal opening STO-Y may have a planar shape of a line or bar extending in the second horizontal direction (the Y direction). Each of the plurality of first horizontal openings STO-X may have a planar shape of a line or bar crossing the second horizontal opening STO-Y and extending in the first horizontal direction (the X direction).

The plurality of first horizontal openings STO-X may be apart from one another in the second horizontal direction (the Y direction) and cross the second horizontal opening STO-Y. The number of first horizontal openings STO-X may be greater than the number of semiconductor layers 110. In some example embodiments, the second horizontal opening STO-Y may extend in the second horizontal direction (the Y direction) along centers in the first horizontal direction (the X direction) of the plurality of first horizontal openings STO-X.

The second horizontal opening STO-Y may extend in the second horizontal direction (the Y direction) between ends of the stacked sacrificial structure 105ST and the stacked semiconductor structure 110ST. The second horizontal opening STO-Y may divide the stacked sacrificial structure 105ST and the stacked semiconductor structure 110ST into two sections. For example, by one second horizontal opening STO-Y, the stacked sacrificial structure 105ST and the stacked semiconductor structure 110ST may be divided into a pair of stack structures apart from each other in the first horizontal direction (the X direction).

Although FIGS. 3A to 3C illustrate only one second horizontal opening STO-Y crossing between the stacked sacrificial structure 105ST and the stacked semiconductor structure 110ST, this is only an example, and example embodiments are not limited thereto. For example, a plurality of second horizontal openings STO-Y apart from each other in the first horizontal direction (the X direction) may cross between the ends of the stacked sacrificial structure 105ST and the stacked semiconductor structure 110ST. By the plurality of second horizontal openings STO-Y, the stacked sacrificial structure 105ST and the stacked semiconductor structure 110ST may be separated into stack structures greater by one than the number of second horizontal openings STO-Y and apart from one another in the first horizontal direction (the X direction).

A horizontal width of the first horizontal opening STO-X in the first horizontal direction (the X direction) may have a value greater than a value of the horizontal width of the second horizontal opening STO-Y in the first horizontal direction (the X direction). For example, the horizontal width of the first horizontal opening STO-X in the first horizontal direction (the X direction) may be about 750 nm, and the horizontal width of the second horizontal opening STO-Y in the first horizontal direction (the X direction) may be about 200 nm.

The horizontal width of the first horizontal opening STO-X in the second horizontal direction (the Y direction) may have a value less than a value of the horizontal width of the first horizontal opening STO-X in the first horizontal direction (the X direction). For example, the horizontal width of the first horizontal opening STO-X in the second horizontal direction (the Y direction) may be about 250 nm. In some example embodiments, the horizontal width of the first horizontal opening STO-X in the second horizontal direction (the Y direction) may have a value greater than a value of the horizontal width of the second horizontal opening STO-Y in the first horizontal direction (the X direction).

In some example embodiments, an interval between the plurality of first horizontal openings STO-X in the second horizontal direction (the Y direction) may have a value approximately identical to a value of the horizontal width of the first horizontal opening STO-X in the second horizontal direction (the Y direction). For example, the interval between the plurality of first horizontal openings STO-X in the second horizontal direction (the Y direction) may be about 250 nm.

Referring to FIGS. 3A to 4C, a plurality of first removal gaps 105G1 are formed by removing a portion of the plurality of sacrificial layers 105 exposed through the first opening STO1. In some example embodiments, the plurality of first removal gaps 105G1 may be formed by performing an isotropic etching process, such as a wet etching process, to remove the portion of the plurality of sacrificial layers 105 exposed through the first opening STO1. The plurality of first removal gaps 105G1 may be formed between the substrate 100 and the semiconductor layer 110 at the bottom of the plurality of semiconductor layers 110, between two semiconductor layers 110 adjacent to each other in the vertical direction, and between the semiconductor layer 110 at the top of the plurality of semiconductor layers 110 and the first insulating layer 200. The plurality of first removal gaps 105G1 may communicate with the first opening STO1.

Portions of the plurality of semiconductor layers 110, which are defined by the plurality of first removal gaps 105G1 and the first openings STO1, may be referred to as a plurality of semiconductor protrusions 110P. The plurality of semiconductor protrusions 110P may include portions of the plurality of semiconductor layers 110 protruding from between the plurality of sacrificial layers 105.

Referring to FIGS. 4A to 5C, a portion of the plurality of semiconductor protrusions 110P exposed through the first opening STO1 and the plurality of first removal gaps 105G1 is removed to form an expanded gap 105GE, which is obtained by expansion of the first removal gap 105G1, and the plurality of semiconductor protrusion structures 110PS obtained by removing the portion of the plurality of semiconductor protrusions 110P.

As a result of removing the portion of the plurality of semiconductor protrusions 110P to form the expanded gap 105GE, a vertical cross-section of the plurality of semiconductor protrusions 110P adjacent to the first opening STO1 may be smaller than a vertical cross-section of the plurality of semiconductor protrusions 110P adjacent to the plurality of sacrificial layers 105. The vertical cross-section of the plurality of semiconductor protrusions 110P, e.g., a vertical cross-section with reference to the first horizontal direction (the X direction) that is a direction in which the plurality of semiconductor protrusions 110P extend, indicates an area on a Y-Z plane. A thickness in the vertical direction (the Z direction) of the plurality of semiconductor protrusions 110P adjacent to the first opening STO1 may be less than a thickness in the vertical direction (the Z direction) of the plurality of semiconductor protrusions 110P adjacent to the plurality of sacrificial layers 105. In addition, a width in the second horizontal direction (the Y direction) of the plurality of semiconductor protrusions 110P) adjacent to the first opening STO1 may be less than a width in the second horizontal direction (the Y direction) of the plurality of semiconductor protrusions 110P adjacent to the plurality of sacrificial layers 105.

In some example embodiments, the plurality of semiconductor protrusion structures 110PS may extend in the first horizontal direction (the X direction), and a vertical cross-section thereof may decrease. For example, the thickness in the vertical direction (the Z direction) and the width in the second horizontal direction (the Y direction) of the plurality of semiconductor protrusion structures 110PS may decrease while extending in the first horizontal direction (the X direction) from the plurality of sacrificial layers 105 toward the first opening STO1.

Referring to FIGS. 5A to 6C, a first insulating opening 2000 is formed by removing a portion of the first insulating layer 200 such that the plurality of semiconductor protrusion structures 110PS and a portion of the stacked sacrificial structure 105ST adjacent to the plurality of semiconductor protrusion structures 110PS are exposed.

In some example embodiments, the first insulating opening 2000 may have a planar shape, including a bar shape having a relatively large horizontal width and extending in the second horizontal direction (the Y direction) or a rectangular shape having a long axis in the second horizontal direction (the Y direction). In the vertical direction (the Z direction), in the first insulating opening 2000, the first opening STO1 and the plurality of semiconductor protrusion structures 110PS may all overlap. In the vertical direction (the Z direction), a portion of the stacked sacrificial structure 105ST and a portion of the stacked semiconductor structure 110ST, which are adjacent to the plurality of semiconductor protrusion structures 110PS, may overlap each other.

Alternatively or additionally in some example embodiments, the first insulating opening 2000 may have an L-shaped planar shape to further expose a portion of the substrate 100 in which the stacked sacrificial structure 105ST and the stacked semiconductor structure 110ST are not arranged.

Referring to FIGS. 6A to 7C, a gate structure 120 is formed. The gate structure 120 covers a surface of a portion of the stacked sacrificial structure 105ST and a surface of the plurality of semiconductor protrusion structures 110PS, which are exposed without being covered by the first insulating layer 200, for example, exposed in the first insulating opening 2000. After forming the gate structure 120, the first insulating layer 200 may be removed.

The gate structure 120 may have a stack structure including a gate dielectric film 122 and a gate electrode film 124. For example, the gate structure 120 may be formed by forming the gate dielectric film 122 covering (e.g. fully or at least partially covering) the surface of the portion of the stacked sacrificial structure 105ST and the surface of the plurality of semiconductor protrusion structures 110PS, which are exposed in the first insulating opening 2000, and then forming the gate electrode film 124 covering the gate dielectric film 122. The gate dielectric film 122 may conformally cover the surface of the portion of the stacked sacrificial structure 105ST and the surface of the plurality of semiconductor protrusion structures 110PS, which are exposed in the first insulating opening 2000, and the gate electrode film 124 may conformally cover the gate dielectric film 122.

In some example embodiments, the gate structure 120 including the gate dielectric film 122 and the gate electrode film 124 may be arbitrarily formed on the surface of the stacked sacrificial structure 105ST and the surface of the plurality of semiconductor protrusion structures 110PS. In some example embodiments, regarding the gate structure 120 including the gate dielectric film 122 and the gate electrode film 124, after being formed on all of a surface of the first insulating layer 200, the surface of the stacked sacrificial structure 105ST, and the surface of the plurality of semiconductor protrusion structures 110PS, the first insulating layer 200 and a portion of the gate structure 120 covering the surface of the first insulating layer 200 may be removed, and the gate structure 120 may remain only on the surface of the portion of the stacked sacrificial structure 105ST and the plurality of semiconductor protrusion structures 110PS exposed in the first insulating opening 2000.

The gate dielectric film 122 may include any one or more material selected from among silicon oxide, a high-k dielectric material having a dielectric constant higher than that of the silicon oxide, and a ferroelectric material. In some example embodiments, the gate dielectric film 122 may have a stack structure including: a first dielectric film including silicon oxide; and a second dielectric film including any one material selected from among the high-k dielectric material and the ferroelectric material. For example, the high-k dielectric material and the ferroelectric material may include any one or more material selected from among hafnium oxide (HfO), hafnium silicate (HfSiO), hafnium oxynitride (HfON), hafnium silicon oxynitride (HfSiON), lanthanium oxide (LaO), lanthanium aluminum oxide (LaAIO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), and lead scandium tantalum oxide (PbScTaO).

In some example embodiments, the gate electrode film 124 may include a conductive barrier film covering the gate dielectric film 122 and a conductive charging layer covering the conductive barrier film. The conductive barrier film may include, for example, a metal, a conductive metal nitride, a conductive metal silicide, or combinations thereof. For example, the conductive barrier film may include TiN. The conductive charging layer may include, for example, doped silicon, Ru, RuO, Pt, PtO, Ir, IrO, SRO(SrRuO), BSRO((Ba,Sr)RuO), CRO(CaRuO), BaRuO, La(Sr,Co)O, Ti, TIN, W, WN, Ta, TaN, TiAIN, TiSiN, TaAIN, TaSiN, or combinations thereof. In some example embodiments, the conductive charging layer may include W.

Referring to FIGS. 8A to 8D, the first opening STO1 and the expanded gap 105GE are filled, a second insulating layer 210 covering the stacked sacrificial structure 105ST and the plurality of semiconductor protrusion structures 110PS is formed, and then a second mask layer MK2 having a second mask opening MKO2 is formed on the second insulating layer 210.

For example, the second insulating layer 210 may include silicon oxide or an insulating material having a permittivity that is lower than a permittivity of silicon oxide. In some example embodiments, the second insulating layer 210 may include one or more of a tetraethyl orthosilicate (TEOS) film or an ultra low K (ULK) film having an ultra low dielectric constant K from about 2.2 to about 2.4. The ULK film may include a SiOC film or SiCOH film.

The second mask layer MK2 may overlap all of the first opening STO1, the expanded gap 105GE, and the plurality of semiconductor protrusion structures 110PS in the vertical direction (the Z direction). For example, the second mask opening MKO2 may not overlap the first opening STO1, the expanded gap 105GE, and the plurality of semiconductor protrusion structures 110PS in the vertical direction (the Z direction). The second mask layer MK2 may overlap, in the vertical direction (the Z direction), the portion of the stacked sacrificial structure 105ST and the portion of the stacked semiconductor structure 110ST adjacent to the plurality of semiconductor protrusion structures 110PS. That is, in a top view, the second mask opening MKO2 may be apart from the first opening STO1, the expanded gap 105GE, and the plurality of semiconductor protrusion structures 110PS.

In some example embodiments, the second mask layers MK2 may overlap all of the gate structure 120 in the vertical direction (the Z direction). That is, the second mask opening MKO2 may not overlap the gate structure 120 in the vertical direction (the Z direction).

The second mask opening MKO2 may include a plurality of narrow mask openings extending in the first horizontal direction (the X direction) and apart from one another in the second horizontal direction (the Y direction) and a wide mask opening MKO-W apart from the plurality of narrow mask openings MKO-N. The wide mask opening MKO-W and the plurality of narrow mask openings MKO-N may be apart from each other and sequentially arranged in the second horizontal direction (the Y direction).

The plurality of narrow mask openings MKO-N may overlap the sacrificial layer 105 at the top of the plurality of sacrificial layers 105 and the semiconductor layer 110 at the top of the plurality of semiconductor layers 110 in the vertical direction (the Z direction). The wide mask opening MKO-W may overlap a portion of the step shape of the stacked sacrificial structure 105ST and the stacked semiconductor structure 110ST in the vertical direction (the Z direction). The plurality of narrow mask openings MKO-N may have a planar shape including a bar shape extending in the first horizontal direction (the X direction) or a rectangular shape having a long axis in the first horizontal direction (the X direction). The wide mask opening MKO-W may have a planar shape including a rectangular shape or a square shape.

The plurality of narrow mask openings MKO-N and the gate structure 120 may be apart from each other in a reference interval ITV in the first horizontal direction (the X direction). For example, the plurality of narrow mask openings MKO-N and the plurality of semiconductor protrusion structures 110PS may be apart from each other by the reference interval ITV. In some example embodiments, the reference interval ITV may be from about tens of nm to about thousands of nm.

Referring to FIGS. 8A to 9D, a portion of each of the second insulating layer 210, the stacked sacrificial structure 105ST, and the stacked semiconductor structure 110ST is removed using the second mask layer MK2 as an etching mask to form the second opening STO2 penetrating the second insulating layer 210, the stacked sacrificial structure 105ST, and the stacked semiconductor structure 110ST. After the second opening STO2 is formed, the second mask layer MK2 may be removed. The substrate 100 may be exposed at a bottom surface of the second opening STO2.

The second opening STO2 may include a plurality of narrow openings STO-N extending in the first horizontal direction (the X direction) and apart from one another in the second horizontal direction (the Y direction) and a wide opening STO-W apart from the plurality of narrow openings STO-N. The wide opening STO-W and the plurality of narrow openings STO-N may be apart from each other and sequentially arranged in the second horizontal direction (the Y direction).

The plurality of narrow openings STO-N may have a planar shape including a bar shape extending in the first horizontal direction (the X direction) or a rectangular shape having a long axis in the first horizontal direction (the X direction). The wide opening STO-W may have a planar shape including a rectangular shape or a square shape. The plurality of narrow openings STO-N and the gate structure 120 may be apart from each other by the reference interval ITV in the first horizontal direction (the X direction). For example, the plurality of narrow openings STO-N and the plurality of semiconductor protrusion structures 110PS may be apart from each other by the reference interval ITV.

Each of the plurality of semiconductor layers 110 may include a wide semiconductor structure 110W, a plurality of narrow semiconductor structures 110B, a connection semiconductor structures 110M, and the plurality of semiconductor protrusion structures 110PS. The plurality of narrow semiconductor structures 110B may each include a portion of the semiconductor layer 110 arranged between the wide opening STO-W and the plurality of narrow openings STO-N. The plurality of narrow semiconductor structures 110B may connect the wide semiconductor structure 110W to the connection semiconductor structures 110M. For example, the plurality of narrow semiconductor structures 110B may have the form of a bridge connecting the wide semiconductor structure 110W to the connection semiconductor structures 110M. The plurality of semiconductor protrusion structures 110PS may be connected to the connection semiconductor structures 110M. The connection semiconductor structures 110M may be between the plurality of semiconductor protrusion structures 110PS and the plurality of narrow semiconductor structures 110B. That is, with reference to the plurality of narrow semiconductor structures 110B, the connection semiconductor structures 110M may be arranged on a side of the plurality of semiconductor protrusion structures 110PS, and the wide semiconductor structure 110W may be arranged opposite to the connection semiconductor structures 110M. The plurality of narrow semiconductor structures 110B may have a planar shape including a bar shape extending in the first horizontal direction (the X direction) or a rectangular shape having a long axis in the first horizontal direction (the X direction). The wide semiconductor structure 110W, the plurality of narrow semiconductor structures 110B, the connection semiconductor structures 110M, and the plurality of semiconductor protrusion structures 110PS, which are included in each of the plurality of semiconductor layers 110, may be integral with one another.

The plurality of narrow semiconductor structures 110B and the gate structure 120 may be apart from each other by the reference interval ITV in the first horizontal direction (the X direction). For example, the plurality of narrow semiconductor structures 110B and the plurality of semiconductor protrusion structures 110PS may be apart from each other by the reference interval ITV.

Referring to FIGS. 9A to 10D, a plurality of second removal gaps 105G2 are formed by removing a portion of the plurality of sacrificial layers 105 through the second opening STO2. In some example embodiments, the plurality of second removal gaps 105G2 may be formed by removing a portion of the plurality of sacrificial layers 105 exposed through the second opening STO2 by performing an isotropic etching process.

The second removal gaps 105G2 may be formed between the narrow semiconductor structures 110B of the plurality of semiconductor layers 110, between the connection semiconductor structures 110M of the plurality of semiconductor layers 110, between the narrow semiconductor structure 110B of the semiconductor layer 110 at the bottom of the plurality of semiconductor layers 110 and the substrate 100, between a connection semiconductor structure 110M of the semiconductor layer 110 at the bottom of the plurality of semiconductor layers 110 and the substrate 100, portions adjacent to the second opening STO2 between the wide semiconductor structures 110W of the plurality of semiconductor layers 110, and a portion adjacent to the second opening STO2 between the substrate 100 and a wide semiconductor structure 110W of the semiconductor layer 110 at the bottom of the plurality of semiconductor layers 110. The plurality of second removal gaps 105G2 may communicate with the second opening STO2.

The connection semiconductor structures 110M of the plurality of semiconductor layers 110 may be apart from the plurality of sacrificial layers 105 without contact. The connection semiconductor structures 110M of the plurality of semiconductor layers 110 may be surrounded by the plurality of second removal gaps 105G2 and the second opening STO2.

Referring to FIGS. 10A to 11B, a portion of the gate structure 120 exposed through the plurality of second removal gaps 105G2 is removed to split the gate structure 120 into a plurality of gate structures 120 respectively located at different vertical levels. The plurality of gate structures 120 split to the different vertical levels may cover the plurality of semiconductor layers 110 respectively located at the different vertical levels and may be apart from one another. The plurality of gate structures 120 that have been split may cover surfaces of the plurality of semiconductor protrusion structures 110PS respectively included in the plurality of semiconductor layers 110 and cover side surfaces of the connection semiconductor structures 110M facing the first opening STO1.

One of the plurality of gate structures 120 that have been split may include: portions surrounding the plurality of semiconductor protrusion structures 110PS included in one of the plurality of semiconductor layers 110; and portions connecting the portions surrounding the plurality of semiconductor protrusion structures 110PS included in the one of the plurality of semiconductor layers 110 and covering a side surface of the connection semiconductor structure 110M included in the one of the plurality of semiconductor layers 110. For example, the plurality of gate structures 120 may each cover a top surface and a bottom surface of the plurality of semiconductor protrusion structures 110PS and two side surfaces connecting the top surface and the bottom surface of each of the plurality of semiconductor protrusion structures 110PS.

Referring to FIGS. 11A to 12C, a second insulating opening 2100 is formed by removing a portion of the second insulating layer 210. The second insulating opening 2100 may overlap end portions of the plurality of semiconductor protrusion structures 110PS included in the semiconductor layer 110 at the top of the plurality of semiconductor layers 110, the end portions facing the second horizontal openings STO-Y in the vertical direction (Z direction). For example, the second insulating opening 2100 may be formed such that, among the plurality of semiconductor protrusion structures 110PS respectively included in the plurality of semiconductor layers 110, portions of the gate structure 120 covering end portions facing the second horizontal opening STO-Y overlapping in the vertical direction (the Z direction) with the plurality of semiconductor protrusion structures 110PS included in the semiconductor layer 110 at the top of the plurality of semiconductor layers 110 are exposed, and the semiconductor protrusion structures 110PS not overlapping in the vertical direction (the Z direction) with the plurality of semiconductor protrusion structures 110PS included in the semiconductor layer 110 at the top of the semiconductor layers 110 and portions of the gate structure 120 covering the same are not exposed.

Next, the portion of the semiconductor protrusion structures 110PS and the portion of the gate structure 120, which are exposed inside the second insulating opening 2100, may be removed. For example, end portions of semiconductor protrusion structure 110PS overlapping in the vertical direction (the Z direction) with the plurality of semiconductor protrusion structures 110PS included in the semiconductor layer 110 at the top of the semiconductor layers 110, the end portions facing the second horizontal opening STO-Y, and portions of the gate structure 120 covering the end portions of the semiconductor protrusion structure 110PS, may be removed. Portions of the semiconductor protrusion structures 110PS overlapping in the vertical direction (the Z direction) with the plurality of semiconductor protrusion structures 110PS included in the semiconductor layer 110 at the top of the semiconductor layers 110 may be exposed inside the second insulating opening 2100.

Referring to FIGS. 12A to 13B, a third insulating layer 220 is formed. In some example embodiments, after removing the second insulating layer 210, the third insulating layer 220 covering the stacked sacrificial structure 105ST and the stacked semiconductor structure 110ST may be formed on the substrate 100. In some other embodiments, an insulating material layer filling the second opening STO2 may be formed such that the insulating material layer and the second insulating layer 210 together form the third insulating layer 220. In some example embodiments, the insulating material layer filling the second opening STO2 may fill the second opening STO2 before the second insulating opening 2100 shown in FIGS. 12A to 12C is completely formed.

Referring to FIGS. 13A to 14B, a portion of the third insulating layer 220 is removed to form a third insulating opening 2200 through which the wide semiconductor structure 110W is exposed, the plurality of sacrificial layers 105 are completely removed and the wide semiconductor structures 110W of the plurality of semiconductor layers 110 are removed, using the third insulating layer 220 as an etching mask, and then a third opening STO3 is formed. The substrate 100 may be exposed at a bottom surface of the third opening STO3, and the plurality of narrow semiconductor structures 110B may be exposed at an inner surface of the third opening STO3.

Referring to FIGS. 14A to 15C, the plurality of narrow semiconductor structures 110B are completely removed through the third opening STO3 to form a plurality of semiconductor openings 1100. In some example embodiments, portions of the connection semiconductor structures 110M may be exposed in the plurality of semiconductor openings 1100.

In some other embodiment, in a process of forming the plurality of semiconductor openings 1100, the entire portion of the plurality of narrow semiconductor structures 110B and portions of the connection semiconductor structures 110M are removed, and by doing so, the plurality of semiconductor protrusion structures 110PS may be exposed in the plurality of semiconductor openings 1100.

Referring to FIGS. 16A and 16B, a lower electrode material layer (not shown) conformally covering surfaces exposed in the plurality of semiconductor openings 1100 is formed. The lower electrode material layer may conformally cover a surface of the third insulating layer 220 and a surface of the connection semiconductor structure 110M exposed in the inside of the plurality of semiconductor openings 1100. Next, a portion of the lower electrode material layer outside the plurality of semiconductor openings 1100, e.g., in the third opening STO3 and a top surface of the third insulating layer 220, may be removed to form a plurality of lower electrode layers 310.

In some example embodiments, the plurality of lower electrode layers 310 may be formed into an empty cylinder shape in which a portion facing the third opening STO3 in the first horizontal direction (the X direction) is open and a portion facing the connection semiconductor structure 110M is closed. Each of the plurality of lower electrode layers 310 may contact the connection semiconductor structure 110M.

In some other embodiments, the plurality of lower electrode layers 310 may be formed in an empty cylinder shape in which the portion facing the third opening STO3 in the first horizontal direction (the X direction) is open and a portion facing the plurality of semiconductor protrusion structures 110PS is closed. Each of the lower electrode layers 310 may contact each of the plurality of semiconductor protrusion structures 110PS.

Next, a capacitor dielectric film 320 conformally covering the plurality of lower electrode layers 310 and an upper electrode layer 330 covering the capacitor dielectric film 320 and filling the plurality of semiconductor openings 1100 may be formed, and by doing so, a plurality of memory elements such as memristors and/or cell capacitors 300 including the plurality of lower electrode layers 310, the capacitor dielectric films 320, and the upper electrode layers 330 may be formed. In some example embodiments, the capacitor dielectric film 320 and the upper electrode layer 330 may each cover an inner surface of the third opening STO3.

The lower electrode layer 310 may include a metal, a conductive metal nitride, a conductive metal silicide, or combinations thereof. For example, the lower electrode layer 310 may include a refractory metal film including a metal, such as cobalt, titanium, nickel, tungsten, and molybdenum. For example, the lower electrode layer 310 may include a metal nitride film, such as a titanium nitride film, a titanium silicon nitride film, a titanium aluminum nitride film, a tantalum nitride film, a tantalum silicon nitride film, a tantalum aluminum nitride film, and a tungsten nitride film.

The capacitor dielectric film 320 may include any one material selected from among a high-k dielectric material having a dielectric constant higher than that of the silicon oxide and a ferroelectric material. For example, the capacitor dielectric film 320 may include at least one of a metal oxide and a dielectric material having a perovskite structure. In some example embodiments, the capacitor dielectric film 320 may include any one material selected from among hafnium oxide (HfO), hafnium silicate (HfSiO), hafnium oxynitride (HfON), hafnium silicon oxynitride (HfSiON), lanthanium oxide (LaO), lanthanium aluminum oxide (LaAIO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PZT), strontium bismuth tantalate (STB), bismuth iron oxide (BFO), strontium titanium oxide (SrTiO), yttrium oxide (YO), aluminum oxide (AlO), and lead scandium tantalum oxide (PbScTaO).

The upper electrode layer 330 may include, for example, doped silicon, Ru, RuO, Pt, PtO, Ir, IrO, SRO(SrRuO), BSRO((Ba,Sr)RuO), CRO(CaRuO), BaRuO, La(Sr,Co)O, Ti, TiN, W, WN, Ta, TaN, TiAIN, TiSiN, TaAIN, TaSiN, or combinations thereof. In some example embodiments, the upper electrode layer 330 may include W.

Referring to FIGS. 16A to 17B, a fourth insulating layer 230 is formed. In some example embodiments, after removing the third insulating layer 220, the fourth insulating layer 230 covering the stacked semiconductor structure 110ST may be formed on the substrate 100. In some other embodiments, an insulating material layer filling the third opening STO3 may be formed, such that the insulating material layer and the third insulating layer 220 together form the fourth insulating layer 230.

In some example embodiments, before forming the fourth insulating layer 230, a portion of the capacitor dielectric film 320 and a portion of the upper electrode layer 330, which cover a portion of an inner surface of the third opening STO3, may be removed. For example, a portion of the capacitor dielectric film 320 and a portion of the upper electrode layer 330, which cover a portion of the fourth insulating layer 230 apart from the plurality of semiconductor openings 1100 in the inner surface of the third opening STO3, may be removed.

Next, a fourth insulating opening 23001 and a fifth insulating opening 23002 are formed by removing a portion of the fourth insulating layer 230 and a portion of the connection semiconductor structures 110M. The fourth insulating opening 23001 may be formed to separate the plurality of cell capacitors 300 and the plurality of semiconductor protrusion structures 110PS from each other. A width of the fourth insulating opening 23001 in the first horizontal direction (the X direction) may be approximately equal to the reference interval ITV. The fifth insulating opening 23002 may be formed in a shape that is approximately similar to that of the second insulating opening 2100 shown in FIGS. 12A to 12C. The plurality of lower electrode layers 310 may be exposed to one of two opposite inner walls of the fourth insulating opening 23001, and end portions at one side of the plurality of semiconductor protrusion structures 110PS may be exposed to another of the two opposite inner walls of the fourth insulating opening 23001. End portions at another side of the plurality of semiconductor protrusion structures 110PS may be exposed at an inner wall of the fifth insulating opening 23002.

Referring to FIGS. 18A and 18B, a semiconductor material layer is grown from the end portions at the one side of the plurality of semiconductor protrusion structures 110PS exposed inside the fourth insulating opening 23001 and the end portions at the other side of the plurality of semiconductor protrusion structures 110PS exposed inside the fifth insulating opening 23002. By doing so, a drain layer 140 is formed on each of the end portions at the one side of the plurality of semiconductor protrusion structures 110PS, and a source layer 130 is formed on each of the end portions at the other side of the plurality of semiconductor protrusion structures 110PS. In some example embodiments, the drain layer 140 may be formed by performing an epitaxial growth process using an end portion of the semiconductor protrusion structure 110PS as a seed, and the source layer 130 may be formed by performing the epitaxial growth process using another end portion of the semiconductor protrusion structure 110PS as a seed.

The source layer 130 and the drain layer 140 may be formed to include impurities having a conductive type that is different from a conductive type of the semiconductor protrusion structure 110PS. For example, the semiconductor protrusion structure 110PS may include impurities of a first conductive type, and the source layer 130 and the drain layer 140 may include impurities of a second conductive type that is different from the impurities of the first conductive type. In some example embodiments, the source layer 130 and the drain layer 140 may be formed by growing a semiconductor material layer including impurities of the second conductive type. In some other embodiments, after forming the source layer 130 and the drain layer 140, impurities of the second conductive type may be injected into the source layer 130 and the drain layer 140.

The source layer 130 and the drain layer 140 may each be formed in a polygon shape having facets. For example, the drain layer 140 may extend with increase in a horizontal width and a thickness in the second horizontal direction (the Y direction) from an end portion of the semiconductor protrusion structure 110PS toward the lower electrode layer 310. In some example embodiments, the drain layer 140 may extend with increase and then decrease in the horizontal width and the thickness in the second horizontal direction (the Y direction) from the end portion of the semiconductor protrusion structure 110PS toward the lower electrode layer 310, and then may contact the lower electrode layer 310. For example, the source layer 130 may extend in the first horizontal direction (the X direction) with increase in a horizontal width and a thickness in the second horizontal direction (the Y direction) from another end of the semiconductor protrusion structure 110PS. In some example embodiments, the source layer 130 may extend in the first horizontal direction (the X direction) with increase and then decrease in the horizontal width and the thickness in the second horizontal direction (the Y direction) from another end of the semiconductor protrusion structure 110PS.

The horizontal width and the thickness in the second horizontal direction (the Y direction) of the end portion of the semiconductor protrusion structure 110PS may be greater than the horizontal width and the thickness in the second horizontal direction (the Y direction) of the other end portion of the semiconductor protrusion structure 110PS. A maximum horizontal width and a maximum thickness in the second horizontal direction (the Y direction) of the drain layer 140 may be greater than a maximum horizontal width and a maximum thickness in the second horizontal direction (the Y direction) of the source layer 130.

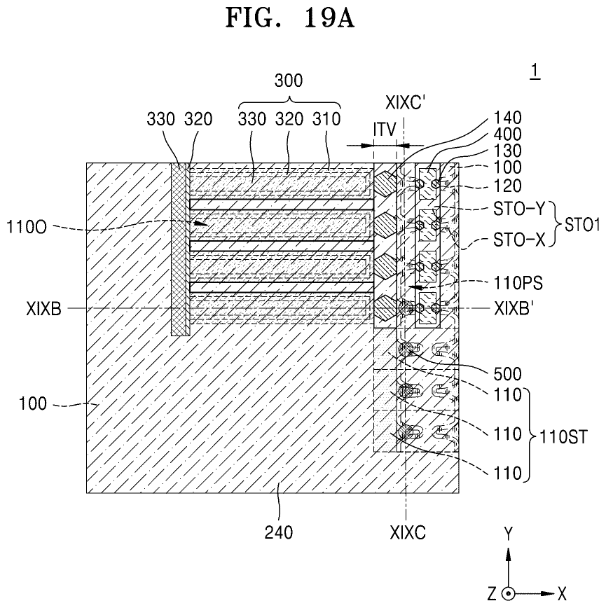

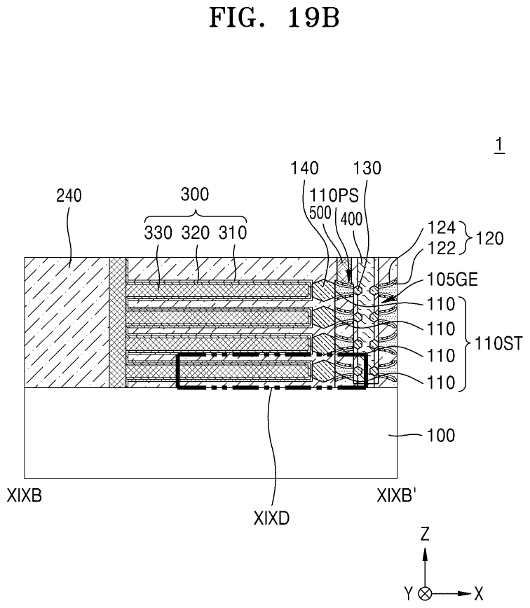

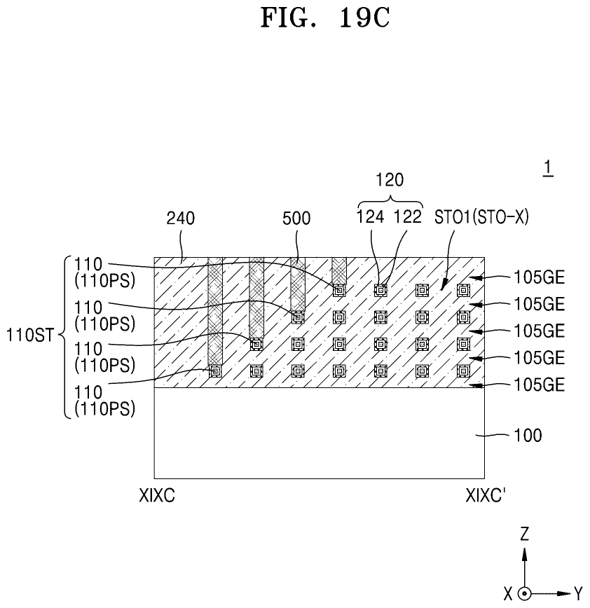

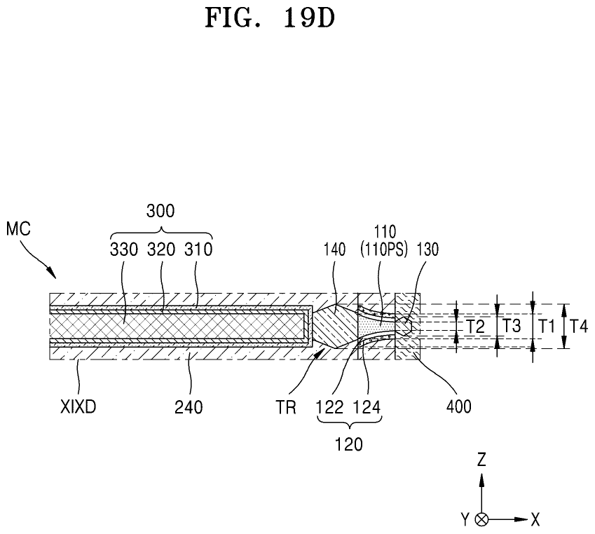

FIGS. 19A to 19D are diagrams of a semiconductor memory device 1 according to various example embodiments. More particularly, FIG. 19A is a top-plan view seen from top; FIGS. 19B and 19C are respectively diagrams of cross-sections taken along line XIXB-XIXB′ shown in FIG. 19A and line XIXC-XIXC′ shown in FIG. 19A, and FIG. 19D is an enlarged diagram of portion XIXD shown in FIG. 19B. In addition, FIGS. 19A to 19D are top-plan views and cross-sectional views corresponding to portion EX shown in FIG. 1A.

Referring to FIGS. 19A to 19D, after a fifth insulating layer 240 is formed, the semiconductor memory device 1 is formed by forming a plurality of bit lines 400 and a plurality of word line contacts 500. In some example embodiments, after removing the fourth insulating layer 230 shown in FIGS. 18A and 18B, the fifth insulating layer 240 covering the stacked semiconductor structure 110ST may be formed on the substrate 100. In some other embodiments, an insulating material layer filling the fourth insulating opening 23001 and the fifth insulating opening 23002 shown in FIGS. 18A and 18B may be formed, such that the insulating material layer and the fourth insulating layer 230 together form the fifth insulating layer 240.

The plurality of bit lines 400 may penetrate the fifth insulating layer 240 and be connected to the source layers 130. The plurality of bit lines 400 may be apart from the plurality of semiconductor protrusion structures 110PS and the gate structure 120 surrounding the plurality of semiconductor protrusion structures 110PS. In some example embodiments, the plurality of bit lines 400 may contact the substrate 100. The plurality of bit lines 400 may surround a portion of the source layers 130. For example, a portion of the source layers 130 may extend into the plurality of bit lines 400. The plurality of bit lines 400 may extend in the vertical direction (the Z direction) and be arranged apart from one another in the second horizontal direction (the Y direction).

In some example embodiments, each of the plurality of bit lines 400 may include a conductive barrier film contacting the source layer 130 and a conductive charging layer covering the conductive barrier film. The conductive barrier film may include, for example, a metal, a conductive metal nitride, a conductive metal silicide, or combinations thereof. For example, the conductive barrier film may include TiN. The conductive charging layer may include, for example, doped silicon, Ru, RuO, Pt, PtO, Ir, IrO, SRO(SrRuO), BSRO((Ba,Sr)RuO), CRO(CaRuO), BaRuO, La(Sr,Co)O, Ti, TiN, W, WN, Ta, TaN, TiAIN, TiSiN, TaAIN, TaSiN, or combinations thereof. In some example embodiments, the conductive charging layer may include W.

The source layers 130 may be connected to each of two side surfaces of each of the plurality of bit lines 400. For example, the source layers 130 may be respectively connected to each of the two sides of the bit line 400 in the first horizontal direction (the X direction). The source layers 130 arranged apart from one another in the vertical direction (the Z direction) may be connected to a side surface of the bit line 400. The source layers 130 connected to the two side surfaces of the plurality of bit lines 400 and the semiconductor protrusion structures 110PS connected to the source layers 130 may be arranged to be mirror symmetric with reference to a straight line extending in the second horizontal direction (the y direction) along the plurality of bit lines 400 or a Y-Z plane.

The plurality of word line contacts 500 may penetrate the fifth insulating layer 240 and be connected to the plurality of gate structures 120 respectively located at different vertical levels. The plurality of word line contacts 500 may be apart from the plurality of bit lines 400 in the first horizontal direction (the X direction). A portion of the fifth insulating layer 240 may fill a gap between the word line contact 500 and the bit line 400 adjacent to each other in the first horizontal direction (the X direction). The plurality of word line contacts 500 may be connected a portion of the plurality of gate structures 120 surrounding the semiconductor protrusion structure 110PS. The plurality of word line contacts 500 may be connected to a portion of the gate structure 120 surrounding one of the plurality of semiconductor protrusion structures 110PS located at a same vertical level. For example, a bottom surface of each of the plurality of word line contacts 500 may contact a portion of the gate electrode film 124 of the gate structure 120 covering the top surface of the semiconductor protrusion structure 110PS. The plurality of word line contacts 500 may be arranged apart from one another in the second horizontal direction (the Y direction). The plurality of word line contacts 500 arranged apart from one another in the second horizontal direction (the Y direction) and connected to the plurality of gate structures 120 respectively located at different levels may respectively have different height, i.e., a length of extension in the vertical direction (the Z direction).

The semiconductor memory device 1 may include the source layer 130, the semiconductor layer 110, and the drain layer 140. The source layer 130, the semiconductor layer 110, and the drain layer 140 may be arranged in the first horizontal direction (the X direction). The source layer 130, the semiconductor layer 110, and the drain layer 140 arranged in the first horizontal direction (the X direction) may be collectively referred to as a horizontal semiconductor structure. The semiconductor layer 110 between the source layer 130 and the drain layer 140 may include the semiconductor protrusion structure 110PS. The semiconductor layer 110 between the source layer 130 and the drain layer 140, i.e., the semiconductor protrusion structure 110PS, may be surrounded by the gate structure 120. The source layer 130, the drain layer 140, the semiconductor layer 110 between the source layer 130 and the drain layer 140, i.e., the semiconductor protrusion structure 110PS, and the gate structure 120 surrounding the semiconductor protrusion structure 110PS may construct a cell transistor TR. The semiconductor layer 110 between the source layer 130 and the drain layer 140, i.e., the semiconductor protrusion structure 110PS, may include a channel area of the cell transistor TR.

The gate structure 120 may extend covering a top surface and a bottom surface of semiconductor protrusion structure 110PS that is a channel area, and two side surfaces connecting the top surface and the bottom surface, and may surround the semiconductor protrusion structure 110PS. The semiconductor protrusion structure 110PS may include impurities of the first conductive type, and the source layer 130 and the drain layer 140 may include impurities of the second conductive type different from the impurities of the first conductive type. In some example embodiments, the first conductive type may indicate p type, and the second conductive type may indicate n type.

The cell transistor TR and the cell capacitor 300 may construct a memory cell MC. The cell capacitor 300 may be connected to the drain layer 140. The bit line 400 may be connected to the source layer 130. The cell capacitor 300, the cell transistor TR, and the bit line 400 may be sequentially arranged in the first horizontal direction (the X direction). The gate structure 120 may generally extend in the second horizontal direction (the Y direction). The bit line 400 may extend in the vertical direction (the Z direction).

The semiconductor memory device 1 may include: a plurality of the memory cells MC apart from one another in the second horizontal direction (the Y direction) and the vertical direction (Z direction) and arranged in columns and rows; the plurality of bit lines 400 connected to the cell transistors TR of the memory cells MC extending in the vertical direction (the Z direction) and arranged in the vertical direction (the Z direction), the plurality of bit lines 400 arranged apart from one another in the second horizontal direction (the Y direction); and the plurality of word line contacts 500 extending in the vertical direction (the Z direction) and arranged apart from one another in the second horizontal direction (the Y direction). On the substrate 100, the fifth insulating layer 240 may cover the plurality of gate structures 120, the source layer 130, the drain layer 140, the cell capacitor 300, the plurality of bit lines 400, and the plurality of word line contacts 500.

Each of the plurality of memory cells MC may include the cell transistor TR and the cell capacitor 300. The cell transistor TR and the cell capacitor 300 included in each of the plurality of memory cells MC may be arranged in the first horizontal direction (the X direction). The cell transistor TR may include the source layer 130, the semiconductor protrusion structure (i.e., the channel area), the drain layer 140, a gate dielectric film 122 surrounding the semiconductor protrusion structure 110PS, and the gate electrode film 124 on the gate dielectric film 122.

A thickness in the vertical direction (the Z direction) and a horizontal width in the second horizontal direction (the Y direction) of an end of the semiconductor protrusion structure 110PS facing the cell capacitor 300 may be greater than a thickness in the vertical direction (the Z direction) and a horizontal width in the second horizontal direction (the y direction) of another end of the semiconductor protrusion structure 110PS. For example, a first thickness T1 in the vertical direction (the Z direction) of the semiconductor protrusion structure 110PS facing the drain layer 140 may have a value greater than a value of a second thickness T2 in the vertical direction (the Z direction) of another end of the semiconductor protrusion structure 110PS facing the source layer 130. The first thickness T1 may be from about 20 nm to about 50 nm, and the second thickness T2 may be from about 5 nm to about 20 nm.

The source layer 130 may extend in the first horizontal direction (the X direction) with increase in a horizontal width and a thickness in the second horizontal direction (the Y direction) from the other end of the semiconductor protrusion structure 110PS. In some example embodiments, the source layer 130 may extend in the first horizontal direction (the X direction) with increase and then decrease in the horizontal width and the thickness in the second horizontal direction (the Y direction) from the other end of the semiconductor protrusion structure 110PS. The thickness in the vertical direction (the Z direction) of the source layer 130 contacting the other end of the semiconductor protrusion structure 110PS may include the second thickness T2. A third thickness T3, i.e., a maximum thickness in the vertical direction (the Z direction) of the source layer 130, may have a value greater than the value of the second thickness T2. For example, the source layer 130 may extend in the first horizontal direction (the X direction) from the other end of the semiconductor protrusion structure 110PS, with increase in the thickness from the second thickness T2 to the third thickness T3 and then decrease.

The drain layer 140 may extend from the end portion of the semiconductor protrusion structure 110PS toward the lower electrode layer 310, with increase in the horizontal width and the thickness in the second horizontal direction (the Y direction). In some example embodiments, the drain layer 140 may extend from the end portion of the semiconductor protrusion structure 110PS toward the lower electrode layer 310, with increase then decrease in the horizontal width and the thickness in the second horizontal direction (the Y direction), and then may contact the lower electrode layer 310. A fourth thickness T4, i.e., a maximum thickness in the vertical direction (the Z direction) of the drain layer 140, may be greater than the first thickness T1. For example, the drain layer 140 may extend from the end of the semiconductor protrusion structure 110PS toward the lower electrode layer 310, with increase in the thickness from the first thickness T1 to the fourth thickness T4 and then decrease.

A thickness of the plurality of semiconductor protrusion structures 110PS in the vertical direction (the Z direction) may decrease from the cell capacitor 300 toward the bit line 400. For example, a thickness in the vertical direction (the Z direction) of the semiconductor protrusion structure 110PS that is the channel area 110C may decrease from the drain layer 140 toward the source layer 130.

The plurality of word line contacts 500 may be connected to the gate electrode films 124 of the plurality of gate structures 120. The plurality of bit lines 400 may be connected to the source layers 130 of the plurality of cell transistors TR. The plurality of cell capacitors 300 may include the plurality of lower electrode layers 310, the capacitor dielectric films 320, and the upper electrode layers 330. The plurality of lower electrode layers 310 may be connected to the drain layers 140 of the plurality of cell transistors TR. In some example embodiments, the capacitor dielectric film 320 and the upper electrode layer 330 may sequentially cover the plurality of lower electrode layers 310, and may each have a plate shape in which a portion extends in the second horizontal direction (the Y direction) and the vertical direction (the Z direction).

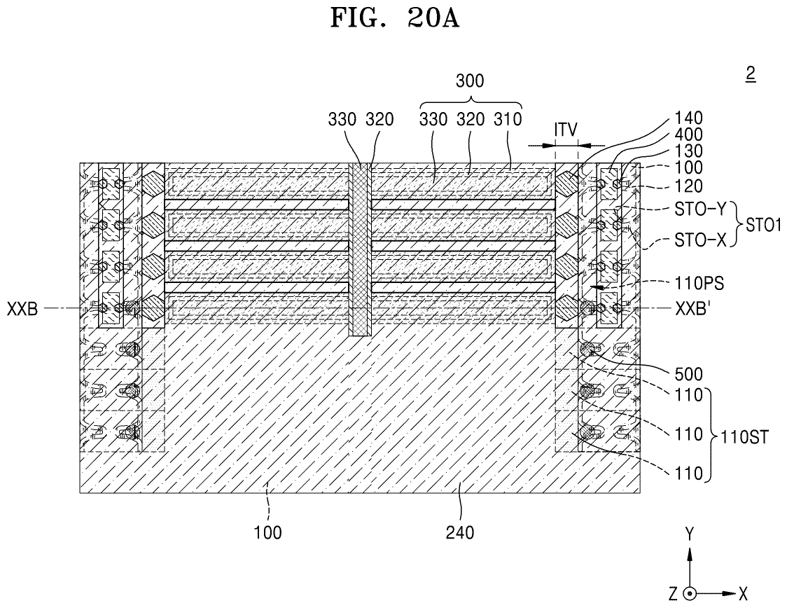

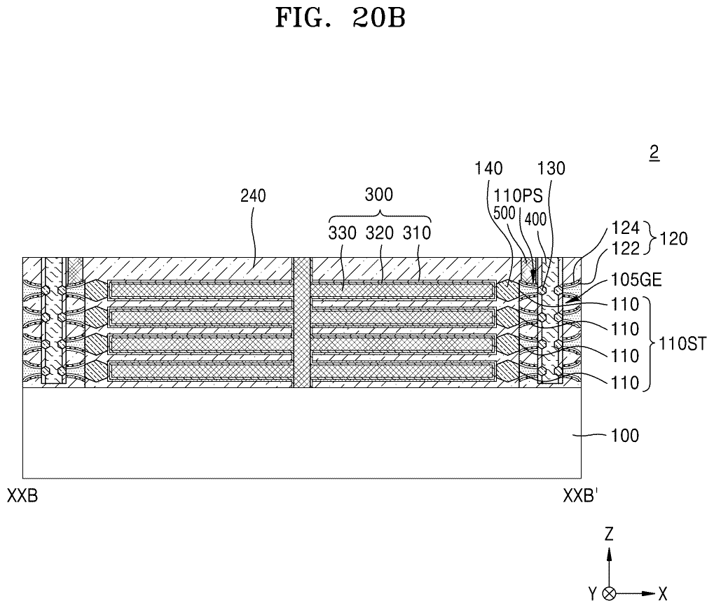

FIGS. 20A and 20B are diagrams of a semiconductor memory device 2 according to some example embodiments. More particularly, FIG. 20A is a top-plan view seen from top, and FIG. 20B is a diagram of a cross-section taken along line XXB-XXB′ shown in FIG. 20. In FIGS. 20A and 20B, same contents as those in FIGS. 19A to 19D may be omitted.

Referring to FIGS. 20A and 20B, the semiconductor memory device 2 may include a plurality of memory cells MC arranged to be mirror symmetric in the first horizontal direction (the X direction) with reference to the upper electrode layer 330. In addition, the memory cells MC may be arranged to be mirror symmetric in the first horizontal direction (the X direction) with reference to the bit line 400.

That is, the semiconductor memory device 2 may include the plurality of memory cells MC arranged apart from one another in the second horizontal direction (the Y direction) and the vertical direction (the Z direction) and arranged in columns and rows, and the plurality of memory cells MC may be alternately arranged to be mirror symmetric with reference to the upper electrode layer 330 and the bit line 400 in the first horizontal direction (the X direction) to construct a memory cell array.

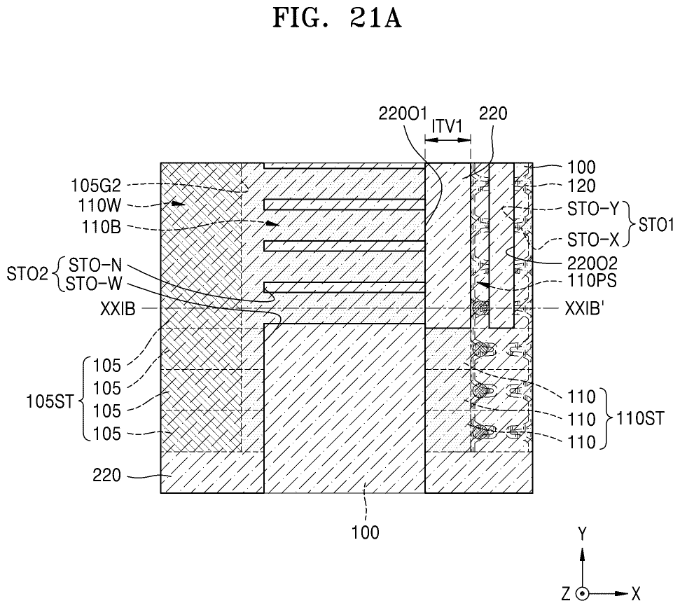

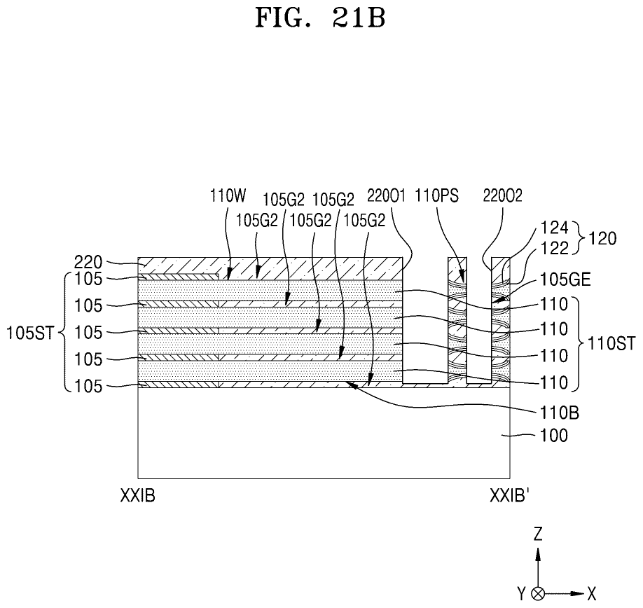

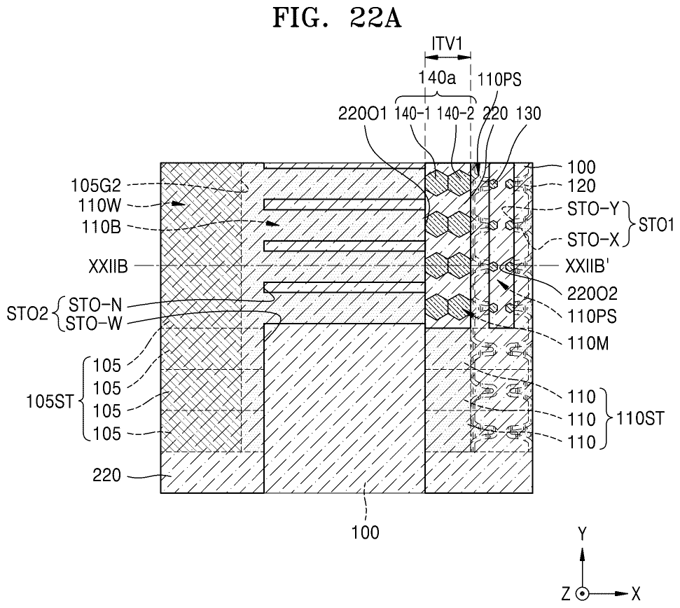

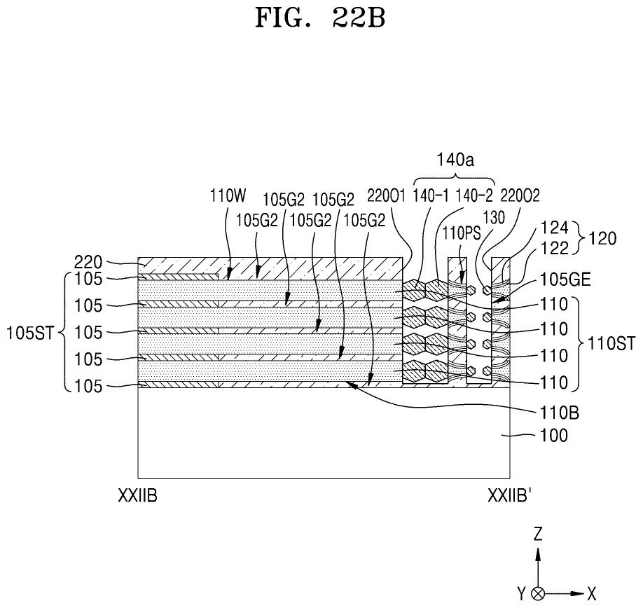

FIGS. 21A to 22B are diagrams shown according to a process order to describe a method of manufacturing a semiconductor memory device according to an example embodiment. More particularly, FIGS. 21A and 22A are each a top-plan view seen from top, and FIGS. 21B and 22B are diagrams of cross-sections respectively taken along line XXIB-XXIB′ shown in FIG. 21A and line XXIIB-XXIIB′ shown in FIG. 22A. In addition, FIGS. 21A to 22B are top-plan views and cross-sectional views corresponding to portion EX shown in FIG. 1A, which illustrate operations after FIGS. 13A and 13B.

Referring to FIGS. 13A, 13B, 21A, and 21B, a fourth insulating opening 22001 and a fifth insulating opening 22002 are formed by removing a portion of the third insulating layer 220. The fourth insulating opening 22001 may be formed to separate the plurality of narrow semiconductor structures 110B and the plurality of semiconductor protrusion structures 110PS from each other. The fifth insulating opening 22002 may be formed in a shape that is approximately similar to that of the second insulating opening 2100 shown in FIGS. 12A to 12C. End portions on a side of the plurality of narrow semiconductor structures 110B may be exposed to one of two opposite inner walls of the fourth insulating opening 22001, and end portions on a side of the plurality of semiconductor protrusion structures 110PS may be exposed to another one of the two opposite inner walls of the fourth insulating opening 22001. The end portions on the other side of the plurality of semiconductor protrusion structures 110PS may be exposed to the inner wall of the fifth insulating layer 22002.

The plurality of narrow semiconductor structures 110B and the gate structure 120 may be apart from each other in a reference interval ITV1 in the first horizontal direction (the X direction). For example, the plurality of narrow semiconductor structures 110B and the plurality of semiconductor protrusion structures 110PS may be apart from each other in the reference interval ITV1. A width in the first horizontal direction (the X direction) of the fourth insulating opening 22001 may be approximately equal to the reference interval ITV1. In some example embodiments, a value of the reference interval ITV1 shown in FIG. 21A may be greater than a value of the reference interval ITV shown in FIGS. 8A to 19A. For example, the value of the reference interval ITV1 shown in FIG. 21A may be about twice the value of the reference interval ITV shown in FIGS. 8A to 19A.

Referring to FIGS. 22A and 22B, a semiconductor material layer is grown from end portions on one side of the plurality of narrow semiconductor structures 110B and end portions on one side of the plurality of semiconductor protrusion structures 110PS exposed inside the fourth insulating opening 22001 and end portions on another side of the plurality of semiconductor protrusion structures 110PS exposed in the fifth insulating opening 22002. By doing so, a drain layer 140a is formed in an interposed manner between the end portions on the one side of the plurality of narrow semiconductor structures 110B and the end portions on the one side of the plurality of semiconductor protrusion structures 110PS facing each other, and the source layer 130 is formed on the end portions on the other side of the plurality of semiconductor protrusion structures 110PS. In some example embodiments, the drain layer 140a may be formed by forming an epitaxial growth process using an end portion of the narrow semiconductor structure 110B and an end portion of the semiconductor protrusion structure 110PS as seeds, and the source layer 130 may be formed by performing an epitaxial growth process using another end portion of the semiconductor protrusion structure 110PS as a seed.

The source layer 130 and the drain layer 140a may be formed to include impurities having a conductive type different from the conductive type of the semiconductor protrusion structure 110PS. For example, the semiconductor protrusion structure 110PS may include impurities of the first conductive type, and the source layer 130 and the drain layer 140a may include impurities of the second conductive type different from the impurities of the first conductive type. In some example embodiments, the source layer 130 and the drain layer 140 may be formed by growing a semiconductor material layer including impurities of the second conductive type. In some other embodiments, after forming the source layer 130 and the drain layer 140a, impurities of the second conductive type may be injected into the source layer 130 and the drain layer 140a.

The source layer 130 may be formed in a polygon shape having facets. For example, the source layer 130 may extend in the first horizontal direction (the X direction) from another end of the semiconductor protrusion structure 110PS, with increase in a horizontal width and the thickness in the second horizontal direction (the Y direction). In some example embodiments, the source layer 130 may extend in the first horizontal direction (the X direction) from another end of the semiconductor protrusion structure 110PS, with increase and then decrease in the horizontal width and the thickness in the second horizontal direction (the Y direction). A maximum horizontal width in the second horizontal direction (the Y direction) and a maximum thickness of the drain layer 140a may be greater than the maximum horizontal width in the second horizontal direction (the Y direction) and the maximum thickness of the source layer 130.

The drain layer 140a may be formed in a shape in which two polygon having facets contact each other. For example, the drain layer 140a may include: a first drain portion 140-1 extending from an end of the narrow semiconductor structure 110B toward the semiconductor protrusion structure 110PS with increase in the horizontal width in the second horizontal direction (the Y direction) and the thickness; and a second drain portion 140-2 extending from an end of the semiconductor protrusion structure 110PS toward the narrow semiconductor structure 110B in the second horizontal direction (the Y direction), with increase in the horizontal width and the thickness. In some example embodiments, the first drain portion 140-1 may extend from an end portion of the narrow semiconductor structure 110B toward the semiconductor protrusion structure 110PS in the second horizontal direction (the Y direction) with increase and then decrease in the horizontal width, and then may contact the second drain portion 140-2. In some example embodiments, the second drain portion 140-2 may extend from an end portion of the semiconductor protrusion structure 110PS toward the narrow semiconductor structure 110B in the second horizontal direction (the Y direction), with increase and then increase in the horizontal width and the thickness, and then may contact the first drain portion 140-1. That is, the drain layer 140a may include the first drain portion 140-1 and the second drain portion 140-2 each having a polygon shape including facets and contacting each other. For example, the first drain portion 140-1 may have a polygon shape having facets extending from the cell capacitor 300 toward an end portion of the semiconductor protrusion structure 110PS, with increase in a thickness thereof from the first thickness T1 to the fourth thickness T4 greater than the first thickness T1, and the second drain portion 140-2 may have a polygon shape having facets extending from an end portion of the semiconductor protrusion structure 110PS toward the cell capacitor with increase in a thickness thereof from the first thickness to the fourth thickness T4. The first drain portion 140-1 and the second drain portion 140-2 may extend toward each other, with decrease in the thickness thereof from the fourth thickness T4, and then may contact each other.

Next, the plurality of cell capacitors 300 may be formed with reference to FIGS. 14A to 16B.

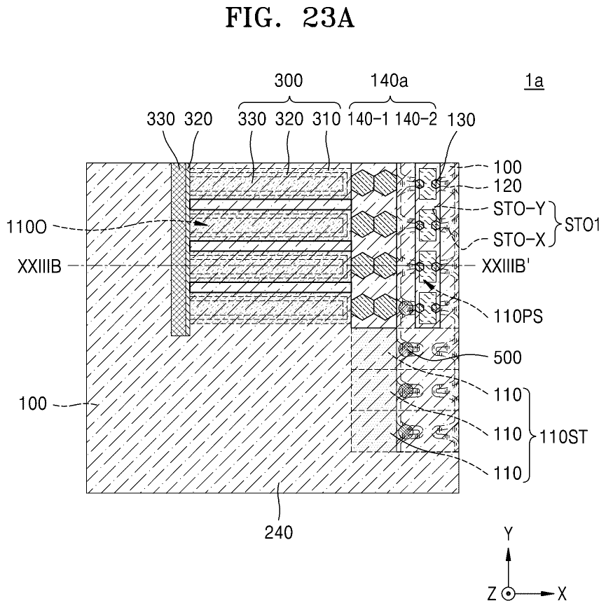

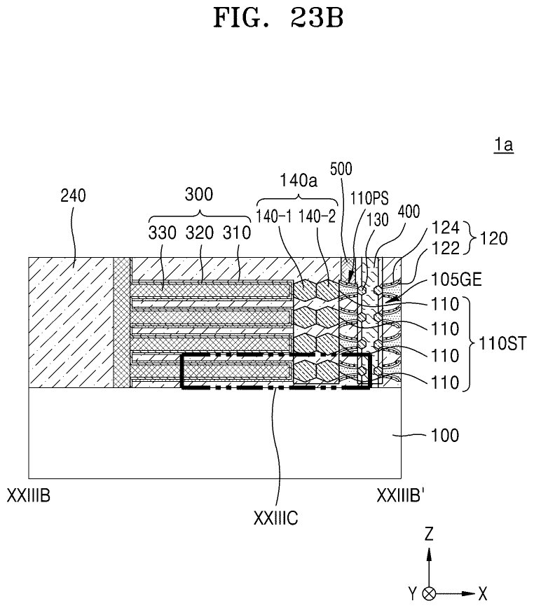

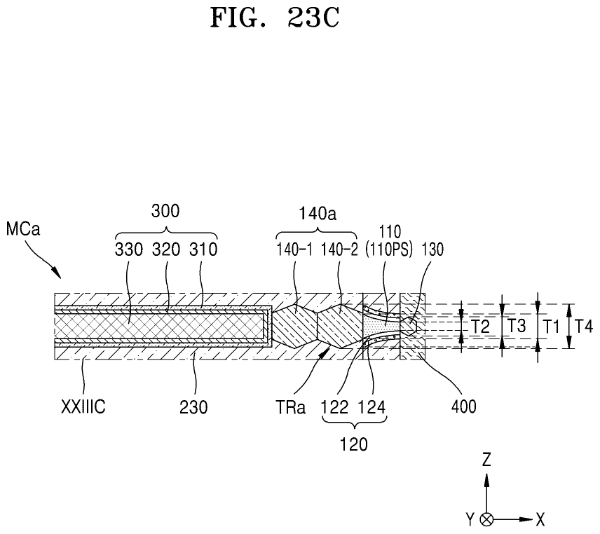

FIGS. 23A to 23C are diagrams of a semiconductor memory device according to some example embodiments. More particularly, FIG. 23A is a top-plan view seen from top; FIG. 23B is a diagram of a cross-section taken along line XXIIIB-XXIIIB′ shown in FIG. 23A; and FIG. 23C is an enlarged diagram of portion XXIIIC shown in FIG. 23B. In addition, FIGS. 23A to 23C are top-plan views and cross-sectional views corresponding to portion EX shown in FIG. 1A.

Referring to FIGS. 23A to 23C, after the fifth insulating layer 240 is formed, a semiconductor memory device 1a is formed by forming the plurality of bit lines 400 and the plurality of word line contacts 500. The plurality of bit lines 400 may penetrate the fifth insulating layer 240 and be connected to the source layers 130. The plurality of word line contacts 500 may penetrate the fifth insulating layer 240 and may be connected to the plurality of gate structures 120 respectively located at different vertical levels.

The semiconductor memory device 1a may include the source layer 130, the semiconductor layer 110, and the drain layer 140a. The source layer 130, the semiconductor layer 110, and the drain layer 140a may be arranged in the first horizontal direction (the X direction). The source layer 130, the semiconductor layer 110, and the drain layer 140a arranged in the first horizontal direction (the X direction) may be collectively referred to as a horizontal semiconductor structure. The semiconductor layer 110 between the source layer 130 and the drain layer 140a may include the semiconductor protrusion structure 110PS. The source layer 130, the drain layer 140a, the semiconductor layer 110 between the source layer 130 and the drain layer 140a, i.e., the semiconductor protrusion structure 110PS, and the gate structure 120 surrounding the semiconductor protrusion structure 110PS may together construct a cell transistor TRa. The semiconductor layer 110 between the source layer 130 and the drain layer 140a, i.e., the semiconductor protrusion structure 110PS, may include a channel area of the cell transistor TRa. The semiconductor protrusion structure 110PS may include impurities of the first conductive type, and the source layer 130 and the drain layer 140a may include impurities of the second conductive type different from the first conductive type.

The cell transistor TRa and the cell capacitor 300 may construct a memory cell MCa. The cell capacitor 300 may be connected to the drain layer 140a. The bit line 400 may be connected to the source layer 130. The cell capacitor 300, the cell transistor TRa, and the bit line 400 may be sequentially arranged in the first horizontal direction (the X direction).

The semiconductor memory device 1a may include: a plurality of memory cells MCa apart from one another in the second horizontal direction (the Y direction) and the vertical direction (the Z direction) and arranged in columns and rows; the plurality of bit lines 400 connected to the cell transistors TRa of the memory cells MCa extending in the vertical direction (the Z direction) and arranged in the vertical direction (the Z direction), the plurality of bit lines 400 arranged apart from one another in the second horizontal direction (the Y direction); and the plurality of word line contacts 500 extending in the vertical direction (the Z direction) and arranged apart from one another in the second horizontal direction (the Y direction). On the substrate 100, the fifth insulating layer 240 may cover the plurality of gate structures 120, the source layer 130, the drain layer 140a, the cell capacitor 300, the plurality of bit lines 400, and the plurality of word line contacts 500.

Each of the plurality of memory cells MCa may include the cell transistor TRa and the cell capacitor 300. The cell transistor TRa and the cell capacitor 300 included in each of the plurality of memory cells MCa may be arranged in the first horizontal direction (the X direction). The cell transistor TRa may include the source layer 130, the semiconductor protrusion structure 110PS (i.e., the channel area), the drain layer 140a, the gate dielectric film 122 surrounding the semiconductor protrusion structure 110PS, and the gate electrode film 124 on the gate dielectric film 122.

The first thickness T1 in the vertical direction (the Z direction) of an end of the semiconductor protrusion structure 110PS facing the drain layer 140a may have a value greater than a value of the second thickness T2 in the vertical direction (the Z direction) of another end of the semiconductor protrusion structure 110PS facing the source layer 130. The third thickness T3, i.e., a maximum thickness in the vertical direction (the Z direction) of the source layer 130 may have a value greater than the value of the second thickness T2, and the fourth thickness T4, i.e., a maximum thickness in the vertical direction (the Z direction) of the drain layer 140a, may have a value greater than the value of the first thickness T1. A thickness in the vertical direction (the Z direction) of the plurality of semiconductor protrusion structures 110PS may decrease from the cell capacitor 300 toward the bit line 400. For example, the thickness in the vertical direction (the Z direction) of the semiconductor protrusion structure 110PS (i.e., the channel area 110C) may decrease from the drain layer 140b toward the source layer 130.

The plurality of word line contacts 500 may be connected to the gate electrode 124 of the plurality of gate structures 120. The plurality of bit lines 400 may be connected to the source layers 130 of the plurality of cell transistors TR. The plurality of cell capacitors 300 may include the plurality of lower electrode layers 310, the capacitor dielectric films 320, and the upper electrode layers 330. The plurality of lower electrode layers 310 may be connected to the drain layers 140a of the plurality of cell transistors TRa.

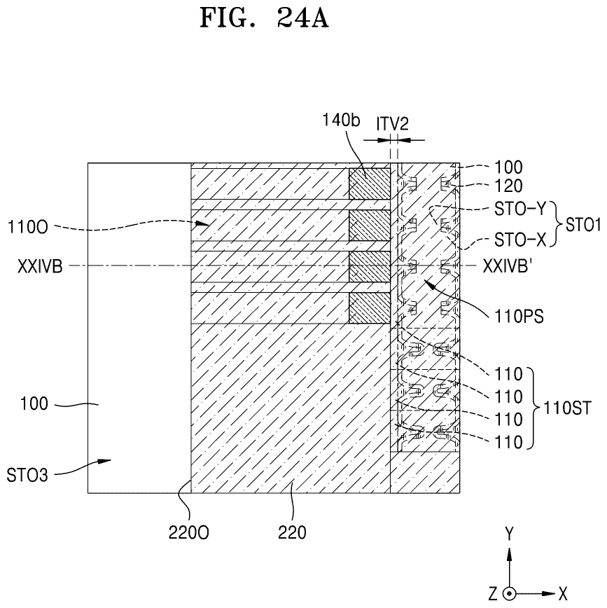

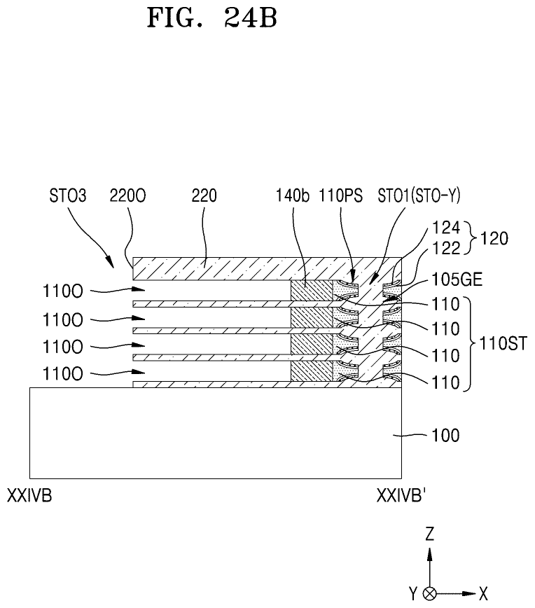

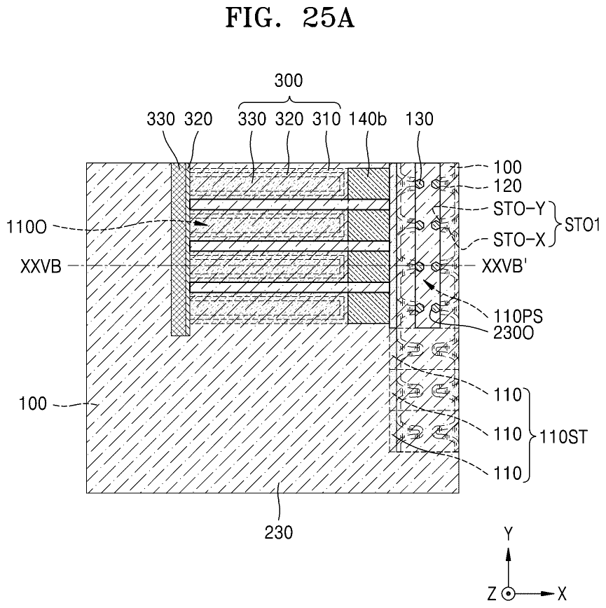

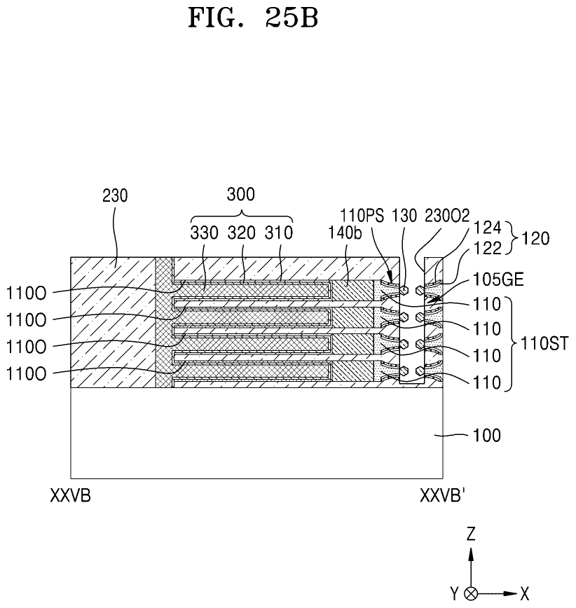

FIGS. 24A to 25B are diagrams shown according to a process order to describe a method of manufacturing a semiconductor memory device according to some example embodiments. More particularly, FIGS. 24A and 25A are each a top-plan view seen from top, and FIGS. 24B and 25B are diagrams of cross-sections respectively taken along line XXIVB-XXIVB′ shown in FIG. 24A and line XXVB-XXVB′ shown in FIG. 25A. In addition, FIGS. 24A to 25B are top-plan views and cross-sectional views corresponding to portion EX shown in FIG. 1A, which illustrate operations after FIGS. 15A and 15B.

Referring to FIGS. 24A and 24B, a semiconductor material layer is grown from the semiconductor layer 110 exposed in each of the plurality of semiconductor openings 1100, to thereby form a drain layer 140b filling a portion of each of the plurality of semiconductor openings 1100. In some example embodiments, the drain layer 140b may be formed by performing an epitaxial growth process using the semiconductor layer 110 exposed in the semiconductor opening 1100 as a seed. In some example embodiments, the drain layer 140b may be formed in a cuboid shape.

In some example embodiments, a portion corresponding to a reference interval ITV2 shown in FIG. 24A may include a portion corresponding to the reference interval ITV shown in FIGS. 8A to 19A. For example, a value of the reference interval ITV2 shown in FIG. 21A may be smaller than a value of the reference interval ITV1 shown in FIGS. 8A to 19A.

Referring to FIGS. 25A and 25B, after the fourth insulating layer 230 is formed, a sixth insulating opening 2300 is formed by removing a portion of the fourth insulating layer 230. The sixth insulating opening 2300 may be formed in a shape that is approximately similar to that of the second insulating opening 2100 shown in FIGS. 12A to 12C. End portions on the other side of the plurality of semiconductor protrusion structures 110PS may be exposed to an inner wall of the sixth insulating opening 2300.

Next, a semiconductor material layer is grown from the end portions on the other side of the plurality of semiconductor protrusion structures 110PS exposed in the sixth insulating opening 2300, to thereby form the source layer 130 on each of the end portions at the other side of the plurality of semiconductor protrusion structures 110PS. In some example embodiments, the source layer 130 may be formed by performing an epitaxial growth process using the end portion on the other side of the semiconductor protrusion structure 110PS as a seed. The end portion on the other side of the plurality of semiconductor protrusion structures 110PS has the horizontal width in the second horizontal direction (the Y direction) and the thickness relatively smaller than those of the end portion of the side of the plurality of semiconductor protrusion structures 110PS. Accordingly, a separation interval between source layers 130 grown from the end portions on the other side of the plurality of semiconductor protrusion structures 110PS are secured, and the source layer 130 adjacent to each other may not contact each other.

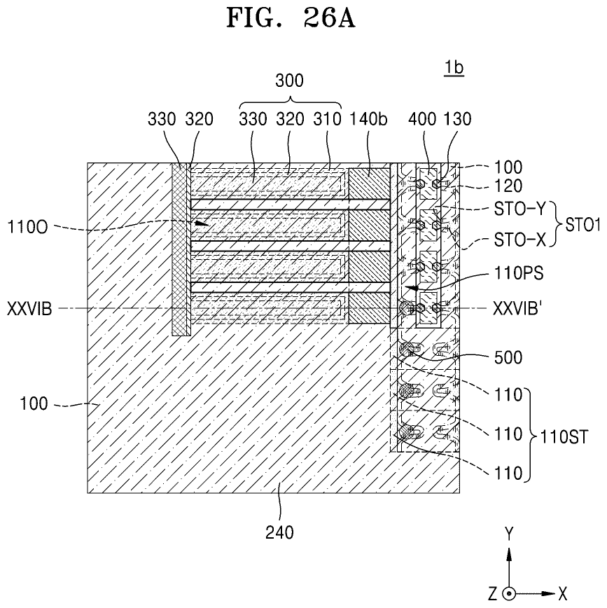

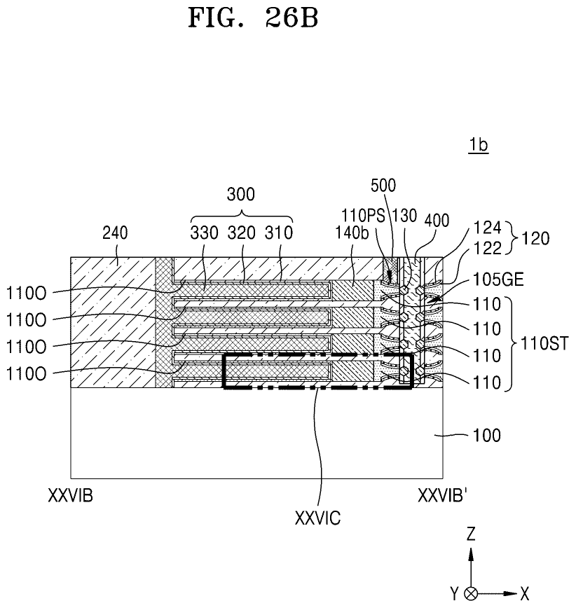

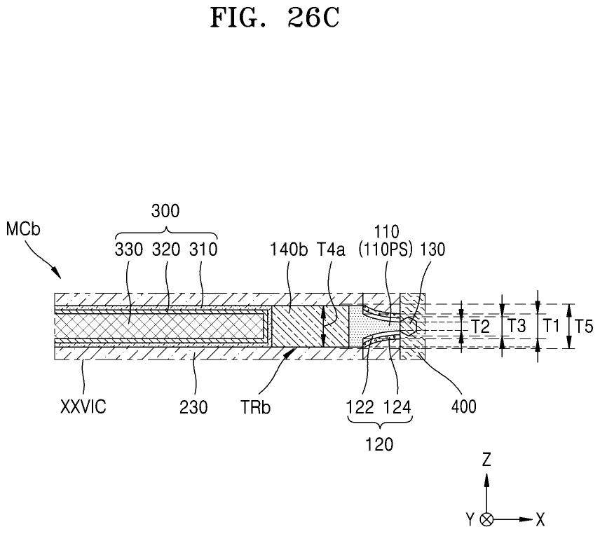

FIGS. 26A to 26C are diagrams of the semiconductor memory device 1b according to various example embodiments. More particularly, FIG. 26A is a top-plan view seen from top; FIG. 26B is a diagram of a cross-section taken along line XXVIB-XXVIB′ shown in FIG. 26A, and FIG. 26C is an enlarged diagram of portion XXVIC shown in FIG. 26B. In addition, FIGS. 26A to 26C are top-plan views and cross-sectional views corresponding to portion EX shown in FIG. 1A.

Referring to FIGS. 26A to 26C, after forming the fifth insulating layer 240, the semiconductor memory device 1b is formed by forming the plurality of bit lines 400 and the plurality of word line contacts 500. The plurality of bit lines 400 may penetrate the fifth insulating layer 240 and be connected to the source layers 130. The plurality of word line contacts 500 may penetrate the fifth insulating layer 240 and may be connected to the plurality of gate structures 120 respectively located at different vertical levels.

The semiconductor memory device 1b may include the source layer 130, the semiconductor layer 110, and the drain layer 140b. The source layer 130, the semiconductor layer 110, and the drain layer 140b may be arranged in the first horizontal direction (the X direction). The source layer 130, the semiconductor layer 110, and the drain layer 140b arranged in the first horizontal direction (the X direction) may be collectively referred to as a horizontal semiconductor structure. The semiconductor layer 110 between the source layer 130 and the drain layer 140b may include the semiconductor protrusion structure 110PS. The source layer 130, the drain layer 140b, the semiconductor layer 110 between the source layer 130 and the drain layer 140b, and the gate structure 120 surrounding the semiconductor protrusion structure 110PS may together construct a cell transistor TRb. The semiconductor layer 110 between the source layer 130 and the drain layer 140b and including the semiconductor protrusion structure 110PS may include a channel area of the cell transistor TRb. The semiconductor layer 110 including the semiconductor protrusion structure 110PS may include impurities of the first conductive type, and the source layer 130 and the drain layer 140b may include impurities of the second conductive type different from the first conductive type.

The cell transistor TRb and the cell capacitor 300 may construct a memory cell MCb. The cell capacitor 300 may be connected to the drain layer 140b. The bit line 400 may be connected to the source layer 130. The cell capacitor 300, the cell transistor TRb, and the bit line 400 may be sequentially arranged in the first horizontal direction (the X direction).

The semiconductor memory device 1b may include: a plurality of memory cells MCb apart from one another in the second horizontal direction (the Y direction) and the vertical direction (the Z direction) and arranged in columns and rows; the plurality of bit lines 400 connected to the cell transistors TRb of the memory cells MCb extending in the vertical direction and arranged in the vertical direction (the Z direction), the plurality of bit lines 400 arranged apart from one another in the second horizontal direction (the Y direction); and the plurality of word line contacts 500 extending in the vertical direction (the Z direction) and arranged apart from one another in the second horizontal direction (the Y direction). On the substrate 100, the fifth insulating layer 240 may cover the plurality of gate structures 120, the source layer 130, the drain layer 140b, the cell capacitor 300, the plurality of bit lines 400, and the plurality of word line contacts 500.

Each of the plurality of memory cells MCb may include the cell transistor TRb and the cell capacitor 300. The cell transistor TRb and the cell capacitor 300 included in each of the plurality of memory cells MCb may be arranged in the first horizontal direction (the X direction). The cell transistor TRb may include the source layer 130, the semiconductor protrusion structure 110PS (i.e., the channel area), the drain layer 140b, the gate dielectric film 122 surrounding the semiconductor protrusion structure 110PS, and the gate electrode film 124 on the gate dielectric film 122.

The first thickness T1 in the vertical direction (the Z direction) of the end portion of the semiconductor protrusion structure 110PS facing the drain layer 140b may have a value greater than the value of the second thickness T2 in the vertical direction (the Z direction) of the other end of the semiconductor protrusion structure 110PS facing the source layer 130. The third thickness T3, i.e., the maximum thickness in the vertical direction (the Z direction) of the source layer 130, may have a value greater than the value of the second thickness T2, and a fourth thickness T4a, i.e., a thickness in the vertical direction (the Z direction) of the drain layer 140b, may be greater than the first thickness T1. A thickness of the plurality of semiconductor protrusion structures 110PS in the vertical direction (the Z direction) may decrease from the cell capacitor 300 toward the bit line 400. For example, the thickness in the vertical direction (the Z direction) of the semiconductor protrusion structure 110PS that is the channel area 110C may decrease from the drain layer 140b toward the source layer 130. In some example embodiments, the semiconductor layer 110 may have a fifth thickness T5 as a maximum thickness. A portion of the semiconductor layer 110 having the fifth thickness T5 may be between the drain layer 140b and the semiconductor protrusion structure 110PS. The fifth thickness T5 may be equal to or greater than the first thickness T1. In some example embodiments, a value of the fifth thickness T5 may be approximately identical to a value of the fourth thickness T4a.

As the drain layer 140b and the cell capacitor 300 are formed in the semiconductor opening 1100, a thickness in the vertical direction (the Z direction) of the cell capacitor 300 in the semiconductor opening 1100 may include a thickness in the vertical direction (the Z direction) of the drain layer 140b, i.e., the fourth thickness T4a; and a horizontal width in the second horizontal direction (the Y direction) of the cell capacitor 300 in the semiconductor opening 1100 may be identical to a horizontal width in the second horizontal direction (the Y direction) of the drain layer 140b. For example, with reference to the first horizontal direction (the X direction), a vertical cross-section of the cell capacitor 300 and the vertical cross-section of the drain layer 140b in the semiconductor opening 1100 may have a same area. A portion of the cell capacitor 300 and a portion of the drain layer 140b contacting each other may have a same thickness, a same horizontal width, and a same vertical cross-sectional area. In some example embodiments, the drain layer 140b may extend with a constant thickness between the semiconductor protrusion structure 110PS and the cell capacitor 300. Therefore, a separation interval between the drain layers 140b may be secured, and the drain layers 140b adjacent to each other may not contact each other.

The plurality of word line contacts 500 may be connected to the gate electrode films 124 of the plurality of gate structures 120. The plurality of bit lines 400 may be connected to the source layers 130 of the plurality of cell transistors TR. The plurality of cell capacitors 300 may include the plurality of lower electrode layers 310, the capacitor dielectric films 320, and the upper electrode layers 330. The plurality of lower electrode layers 310 may be connected to the drain layers 140b of the plurality of cell transistors TRb.

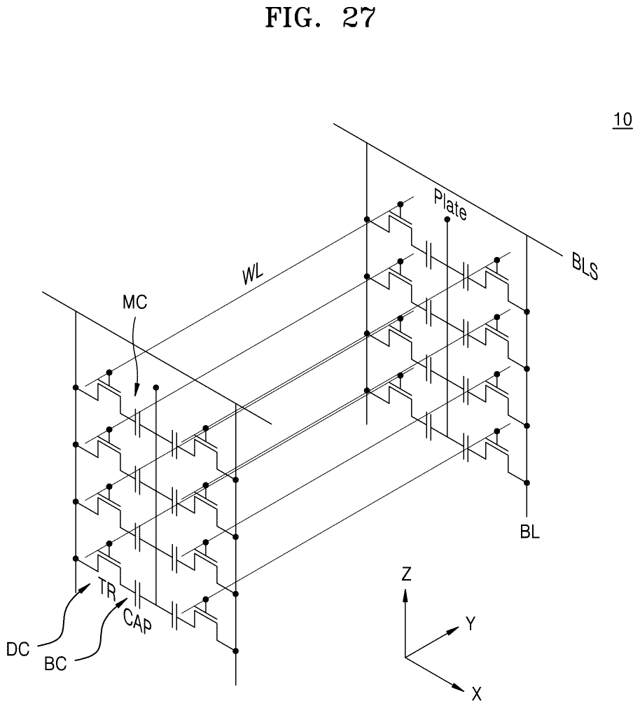

FIG. 27 is an equivalent circuit diagram of a cell array of a semiconductor memory device 10 according to some example embodiments.

Referring to FIG. 27, the semiconductor memory device 10 may include the plurality of memory cells MC including the cell transistors TR and the cell capacitors CAP arranged in the first horizontal direction (the X direction) and connected to each other. The plurality of memory cells MC may be apart from one another in the second horizontal direction (the Y direction) and the vertical direction (the Z direction) and arranged in columns and rows. The cell capacitor CAP may indicate the cell capacitor 300 shown in FIGS. 19A to 19D, FIGS. 23A to 23C, and FIGS. 26A to 26C. The cell transistor TR may indicate the cell transistor TR shown in FIGS. 19A to 19D, the cell transistor TRa shown in FIGS. 23A to 23C, or the cell transistor TRb shown in FIGS. 26A to 26C. The memory cell MC may indicate the memory cell MC shown in FIGS. 19A to 19D, the memory cell MCa shown in FIGS. 23A to 23C, or the memory cell MCb shown in FIGS. 26A to 26C.

The plurality of word lines WL may extend in the second horizontal direction (the Y direction) and may be arranged apart from one another in the first horizontal direction (the X direction) and the vertical direction (the Z direction). The word line WL may indicate the gate electrode film 124 shown in FIGS. 19A to 19D, 23A to 23C, and 26A to 26C. A plurality of bit lines BL may extend in the vertical direction (the Z direction) and may be arranged apart from one another in the first horizontal direction (the X direction) and the second horizontal direction (the Y direction). The bit line BL may indicate the bit line 400 shown in FIGS. 19A to 19D, 23A to 23C, and 26A to 26C.

In some example embodiments, some of the plurality of bit lines BL may be connected to each other by a bit line strapping line BLS extending in the first horizontal direction (the X direction). For example, the bit line strapping line BLS may connect bit lines BL aligned in the first horizontal direction (the X direction) from among the plurality of bit lines BL.

The plurality of cell capacitors CAP may be commonly connected to an upper electrode PLATE extending in the second horizontal direction (the Y direction) and the vertical direction (the Z direction). The upper electrode PLATE may indicate the upper electrode layer 330 shown in FIGS. 19A to 19D, 23A to 23C, and 26A to 26C. For convenience of illustration, FIG. 27 illustrates that each of the upper electrodes PLATE aligned in the second horizontal direction (the Y direction) extends in the vertical direction (the Z direction). However, the upper electrodes PLATES aligned in the second horizontal direction (the Y direction) may be integral with one another. The plurality of memory cells MC may be arranged in a mirror symmetry in the first horizontal direction (the X direction) with reference to the upper electrode PLATE.

The plurality of memory cells MC may be arranged to be mirror symmetric with reference to a surface extending in the second horizontal direction (the Y direction) and the vertical direction (the Z direction) and in which the upper electrode PLATE is arranged. In addition, as shown in FIGS. 20A and 20B, the plurality of memory cells MC may be arranged to be mirror symmetric with reference to a surface extending in the second horizontal direction (the Y direction) and the vertical direction (the Z direction) and in which the bit lines BL aligned in the second horizontal direction (the Y direction) are arranged. The cell capacitors CAP and the cell transistors TR aligned in the first horizontal direction (the X direction) may be arranged to be mirror symmetric with reference to a surface extending in the second horizontal direction (the Y direction) and the vertical direction (the Z direction) and in which the upper electrodes PLATE are arranged. In addition, the cell capacitor CAP and the cell transistor TR aligned in the first horizontal direction (the X direction) may be arranged to be mirror symmetric with reference to a surface extending in the second horizontal direction (the Y direction) and the vertical direction (the Z direction) and in which the bit lines BL aligned in the second horizontal direction (the Y direction) are arranged, as shown in FIGS. 19A to 19D, 23A to 23C, and 26A to 26C.

The cell transistor may be connected to the bit line BL through DC and may be connected to the cell capacitor CAP through BC. The DC may indicate the source layer 130 shown in FIGS. 19A to 19D, 23A to 23C, and 26A to 26C. The DC may indicate the drain layer 140 shown in FIGS. 19A to 19D, the drain layer 140a shown in FIGS. 23A to 23C, and the drain layer 140b shown in FIGS. 26A to 26C.

The semiconductor memory device 10 may indicate one or more of the semiconductor memory device 1 shown in FIGS. 19A to 19D, the semiconductor memory device 2 shown in FIGS. 20A and 20B, the semiconductor memory device 1a shown in FIGS. 23A to 23C, and the semiconductor memory device 1b shown in FIGS. 26A to 26C.

Referring to FIGS. 1A to 27, the semiconductor memory device 1, 2, la, 1b, or 10 according to the inventive concept include the plurality of memory cells MC, MCa, or MCb arranged apart from one another in the second horizontal direction (the Y direction) and the vertical direction (the Z direction) and arranged in columns and rows, and the plurality of memory cells MC, MCa, or MCb may be alternately arranged to be mirror symmetric in the first horizontal direction (the X direction), and thus, the integration of the semiconductor memory device 1, 2, la, 1b, or 10 may be improved.

Alternatively or additionally, even when an element included in the sacrificial layer 105, e.g., Ge, is diffused to a portion of the semiconductor layer 110, the semiconductor protrusion structure 110PS is formed by removing a portion of the semiconductor layer 110 contacting the sacrificial layer 105, and accordingly, operation properties of the cell transistor TR, TRa, or TRb including the semiconductor protrusion structure 110PS as the channel area may be improved.

Alternatively or additionally, as the semiconductor protrusion structure 110PS is formed by removing a portion of the semiconductor layer 110, a gap between two semiconductor protrusion structures 110PS adjacent to each other, i.e., the expanded gap 105GE, may increase in size. Accordingly, as the gate electrode film 124 surrounding the semiconductor protrusion structure 110PS may be formed in a relatively great thickness, a resistance of the gate electrode film 124 may be reduced.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Moreover, when the words “generally” and “substantially” are used in connection with material composition, it is intended that exactitude of the material is not required but that latitude for the material is within the scope of the disclosure.

Further, regardless of whether numerical values or shapes are modified as “about” or “substantially,” it will be understood that these values and shapes should be construed as including a manufacturing or operational tolerance (e.g., ±10%) around the stated numerical values or shapes. Thus, while the term “same,” “identical,” or “equal” is used in description of example embodiments, it should be understood that some imprecisions may exist. Thus, when one element or one numerical value is referred to as being the same as another element or equal to another numerical value, it should be understood that an element or a numerical value is the same as another element or another numerical value within a desired manufacturing or operational tolerance range (e.g., ±10%).

While inventive concepts have been particularly shown and described with reference to embodiments thereof, it will be understood that various changes in form and details may be made therein without departing from the spirit and scope of the following claims. Furthermore, example embodiments are not necessarily mutually exclusive with one another. For example, some example embodiments may include one or more features described with reference to one or more figures and may also include one or more other features described with reference to one or more other drawings.

What is claimed is:

1. A semiconductor memory device comprising:
a source layer, a semiconductor layer comprising a semiconductor protrusion structure, and a drain layer that are arranged in a first horizontal direction on a substrate;
a cell capacitor on the substrate, extending in the first horizontal direction, and comprising an upper electrode layer, a capacitor dielectric film, and lower electrode layer connected to the drain layer;
a bit line on the substrate, extending in a vertical direction and connected to the source layer; and
a gate structure covering the semiconductor protrusion structure and comprising a gate dielectric film on the semiconductor protrusion structure and a gate electrode film on the gate dielectric film,
wherein a value of a first thickness of an end portion of the semiconductor protrusion structure facing the drain layer is greater than a value of a second thickness of another end portion of the semiconductor protrusion structure facing the source layer, and
the source layer has the second thickness at the other end portion of the semiconductor protrusion structure and has a third thickness, which is greater than the second thickness, as a maximum thickness.

2. The semiconductor memory device of claim 1, wherein the source layer comprises a polygon shape having facets.

3. The semiconductor memory device of claim 2, wherein the drain layer comprises a polygon shape having facets.

4. The semiconductor memory device of claim 2, wherein the drain layer has a cuboid shape.

5. The semiconductor memory device of claim 2, wherein the drain layer has a shape in which two polygons having facets contact each other.

6. The semiconductor memory device of claim 1, wherein
the drain layer and the source layer respectively contact the end portion and the other end portion of the semiconductor protrusion structure, and
a value of a maximum thickness of the drain layer is greater than a value of the first thickness.

7. The semiconductor memory device of claim 5, wherein a maximum thickness of the semiconductor layer is equal to the maximum thickness of the drain layer.

8. The semiconductor memory device of claim 1, wherein a value of a horizontal width of the end portion of the semiconductor protrusion structure facing the drain layer is greater than a value of the horizontal width of the other end portion of the semiconductor protrusion structure facing the source layer.

9. The semiconductor memory device of claim 1, wherein the semiconductor protrusion structure extends from the drain layer toward the source layer with a decrease in a vertical cross-section of the semiconductor protrusion structure.

10. The semiconductor memory device of claim 1, further comprising:
a word line contact connected to the gate structure and extending in the vertical direction,
wherein a bottom surface of the word line contact contacts a portion of the gate electrode film covering a top surface of the semiconductor protrusion structure.

11. A semiconductor memory device comprising:
a plurality of horizontal semiconductor structures each comprising a source layer, a semiconductor layer comprising a semiconductor protrusion structure, and a drain layer arranged in a first horizontal direction on a substrate, wherein the plurality of horizontal semiconductor structures are apart from one another in columns in a second horizontal direction, which is orthogonal to the first horizontal direction, and in rows in a vertical direction;
a plurality of cell capacitors extending in the first horizontal direction from the plurality of horizontal semiconductor structures and each comprising a lower electrode layer connected to the drain layer of each of the plurality of horizontal semiconductor structures, a capacitor dielectric film covering the lower electrode layer, and an upper electrode layer covering the capacitor dielectric film;
a plurality of bit lines extending in the vertical direction on the substrate, apart from one another in the second horizontal direction and connected to the drain layers of the plurality of horizontal semiconductor structures; and
a plurality of gate structures covering the semiconductor protrusion structures of the plurality of semiconductor layers and extending in the second horizontal direction, the plurality of gate structures each comprising a gate dielectric film on the semiconductor protrusion structure and a gate electrode film on the gate dielectric film,
wherein each of the plurality of semiconductor protrusion structures extends from an end of the semiconductor protrusion structure facing each of the plurality of drain layers to another end of the semiconductor protrusion structure facing each of the source layers, with a decrease from a first thickness to a second thickness that is less than the first thickness, and
each of the source layers has a polygon shape having facets extending from the other end of each of the semiconductor protrusion structures, with an increase from the second thickness to a third thickness that is greater than the second thickness in the first horizontal direction.

12. The semiconductor memory device of claim 11, wherein each of the drain layers has a polygon shape having facets extending from an end of each of the plurality of semiconductor protrusion structures to each of the plurality of cell capacitors, with an increase from the first thickness to a fourth thickness that is greater than the first thickness.

13. The semiconductor memory device of claim 12, wherein each of the drain layers extends toward each of the plurality of cell capacitors with a decrease in a thickness from the fourth thickness and then contacts respective ones of each of the plurality of cell capacitors.

14. The semiconductor memory device of claim 11, wherein each of the drain layers has the first thickness between each of the plurality of semiconductor protrusion structures and each of the plurality of cell capacitors.

15. The semiconductor memory device of claim 11, wherein, in each of the drain layers,
a first drain portion and a second drain portion contact each other, the first drain portion having a polygon shape having facets extending from respective ones of each of the plurality of cell capacitors to an end of respective ones of each of the plurality of semiconductor protrusion structures with increase from the first thickness to a thickness that is greater than the first thickness, the second drain portion having a polygon shape having facets extending from the end of each of the plurality of semiconductor protrusion structures to each of the plurality of the respective ones of the cell capacitors with increase from the first thickness to a thickness that is greater than the first thickness.

16. The semiconductor memory device of claim 11, wherein a maximum thickness of each of the drain layers is greater than a maximum thickness of each of the source layers.

17. The semiconductor memory device of claim 11, further comprising:
a plurality of word line contacts extending in the vertical direction, connected to the plurality of gate structures, and arranged apart from one another in the second horizontal direction, wherein the plurality of word line contacts are connected to gate structures at different vertical levels among the plurality of gate structures.

18. The semiconductor memory device of claim 17, wherein
the plurality of gate structures each cover a top surface and a bottom surface of each of the semiconductor protrusion structures and two side surfaces connecting the top surface and the bottom surface, to surround each of the semiconductor protrusion structures, and
a bottom surface of each of the plurality of word line contacts is in contact with a portion of the plurality of gate films covering a top surface of any one of the plurality of semiconductor protrusion structures.

19. A semiconductor memory device comprising:
a plurality of horizontal semiconductor structures on a substrate and arranged in a first horizontal direction, each comprising a source layer, a semiconductor layer comprising a semiconductor protrusion structure, and a drain layer, the plurality of horizontal semiconductor structures arranged apart in columns in a second horizontal direction orthogonal to the first horizontal direction and in rows in a vertical direction;
a plurality of cell capacitors extending in the first horizontal direction from the plurality of horizontal semiconductor structures, the plurality of cell capacitors each comprising a lower electrode layer connected to the source layer of a respective one of each of the plurality of horizontal semiconductor structures, a capacitor dielectric film covering each of the plurality of lower electrode layers, and an upper electrode layer covering the capacitor dielectric film;
a plurality of bit lines extending in the vertical direction on the substrate, connected to the source layers of horizontal semiconductor structures arranged apart from one another in the vertical direction from among the plurality of horizontal semiconductor structures, and arranged apart from one another in the second horizontal direction;
a plurality of gate structures surrounding the semiconductor protrusion structures, apart from one another in the second horizontal direction from among the plurality of semiconductor protrusion structures and extending in the second horizontal direction, the plurality of gate structure each comprising a gate dielectric film on the semiconductor protrusion structure and a gate electrode film on the gate dielectric film; and
a plurality of word line contacts extending in the vertical direction and arranged apart from one another in the second horizontal direction, wherein the plurality of word line contacts are arranged apart from the plurality of bit lines in the first horizontal direction and are connected to the gate electrode film of each of the plurality of gate structures,
wherein each of the plurality of semiconductor protrusion structures extends with a decrease from a first thickness to a second thickness that is less than the first thickness, from an end of the semiconductor protrusion structure facing each of the plurality of drain layers to another end of the semiconductor protrusion structure facing each of the source layers,
each of the source layers extends in the first horizontal direction from the other end of each of the semiconductor protrusion structures, with an increase in a thickness from the second thickness to a third thickness that is greater than the second thickness, and
a thickness of each of the drain layers extends in a constant thickness between an end of each of the semiconductor protrusion structures and each of the plurality of cell capacitors.

20. The semiconductor memory device of claim 19, wherein,
in the vertical direction, the first thickness of an end of the semiconductor protrusion structure facing the drain layer is 20 nm to 50 nm, and
the second thickness of another end of the semiconductor protrusion structure facing the source layer is from 5 nm to 20 nm.
